(19) United States
(12) Patent Application Publication
(10) Pub. No.: US 2023/0371337 A1
(43) Pub. Date: Nov. 16, 2023

(54) DISPLAY DEVICE

(71) Applicant: Japan Display Inc., Tokyo (JP)

(72) Inventors: Sho YANAGISAWA, Tokyo (JP); Mitsugu TAMEKAWA, Tokyo (JP); Kota MAKISHI, Tokyo (JP)

(73) Assignee: Japan Display Inc., Tokyo (JP)

(21) Appl. No.: 18/313,396

(22) Filed: May 8, 2023

(30) Foreign Application Priority Data
May 10, 2022 (JP) 2022-077754

(51) Int. Cl. H10K 59/35

(52) U.S. Cl. CPC H10K 59/353

(57) ABSTRACT

A display device according to an embodiment of the present disclosure comprises a display area arranged with a plurality of pixels including a first pixel containing a first deposition material and a second pixel containing a second deposition material and having the same size as the first pixel and a non-display area located around the display area including a first area adjacent to one side of the display area and a second area adjacent to the other side opposite the one side of the display area. The first area is arranged with a first deposition pattern containing the first deposition material, and the second area is arranged with a second deposition pattern containing the second deposition material and having the same size as the first deposition pattern. The second deposition pattern is not arranged in the first area.

### CROSS-REFERENCE TO RELATED APPLICATION

This application claims the benefit of priority to Japanese Patent Application No. 2022-077754, filed on May 10, 2022, the entire contents of which are incorporated herein by reference.

### FIELD

The present disclosure relates to a display device.

### BACKGROUND

In recent years, an organic electroluminescence display device (hereinafter, referred to as an organic EL display device) using an organic electroluminescence element (hereinafter, referred to as an organic EL element) as a light-emitting element has been known. The organic EL element includes an anode electrode, a cathode electrode, and a layer (hereinafter, referred to as “organic EL layer”) containing an organic electroluminescent material (hereinafter, referred to as an organic EL material) arranged between the electrodes. For example, the organic EL layer includes functional layers such as a light-emitting layer, an electron transport layer, and a hole transport layer. The organic EL element emits light by applying a voltage to each of the anode electrode and the cathode electrode to cause a current to flow between the anode electrode and the cathode electrode.

Generally, in a process of manufacturing the organic EL display device, a vacuum-deposition method is used to form the organic EL layer. In the vacuum-deposition method, a deposition mask is placed close to a substrate, and the organic EL material is deposited on the substrate via the deposition mask. The deposition mask has a plurality of openings. Since the organic EL material heated and vaporized by a heater passes through the plurality of openings and reaches a surface of the substrate and is deposited, the organic EL layer can be selectively formed at positions corresponding to the plurality of openings arranged in the deposition mask.

Each pixel of the organic EL display device may be comprised a first pixel (R pixel) that emits red light, a second pixel (G pixel) that emits green light, and a third pixel (B pixel) that emits blue light. Each of the RGB pixels includes the organic EL element that emits red light, green light, or blue light. An opening size of the RGB pixels and an opening size of the deposition mask used for forming the organic EL layers of the RGB pixel are determined in view of customer requirements, optical characteristics, element performance, and the like. Generally, the deposition mask has low accuracy in opening positions, low yields, and high manufacturing costs. The cost of manufacturing the deposition mask is passed on to the price of the display device manufactured using the deposition mask.

Generally, a dedicated deposition mask for forming the organic EL layer of each of the RGB pixels is used in a step of forming the organic EL layers of the RGB pixels. In order to reduce the cost of manufacturing the display device, it is conceivable that the deposition mask used to form the organic EL element is also used in a step of forming a sub-pixel, which emits two or more different colors. For example, Japanese laid-open patent publication No. 2003-59671 discloses a manufacturing method for forming the organic EL layer by shifting one film-forming mask by one sub-pixel in a step of forming the organic EL layer that emits different colors of light.

### SUMMARY

A display device according to an embodiment of the present disclosure comprises a display area arranged with a plurality of pixels, the plurality of pixels including a first pixel containing a first deposition material emitting a first color light and a second pixel containing a second deposition material emitting a second color light different from the first color light and having the same size as the first pixel, and a non-display area located around the display area, the non-display area including a first area adjacent to one side of the display area and a second area adjacent to the other side opposite the one side of the display area. The first area is arranged with a first deposition pattern containing the first deposition material, and the second area is arranged with a second deposition pattern containing the second deposition material and having the same size as the first deposition pattern. The second deposition pattern is not arranged in the first area.

A display device according to an embodiment of the present disclosure comprises a display area arranged with a plurality of pixels, the plurality of pixels including a first pixel containing a first deposition material emitting a first color light and a second pixel containing a second deposition material emitting a second color light different from the first color light and having the same size as the first pixel and a non-display area located around the display area, the non-display area including a first area adjacent to one side of the display area and a second area adjacent to the other side opposite the one side of the display area. The first area and the second area are arranged with a first deposition pattern containing the first deposition material and a second deposition pattern containing the second deposition material and having the same size as the first deposition pattern. The number of the second deposition patterns is greater than the number of the first deposition patterns in the second area.

A display device according to an embodiment of the present disclosure comprises a display area arranged with a plurality of pixels, the plurality of pixels including a first pixel containing a first deposition material emitting a first color light and a second pixel containing a second deposition material emitting a second color light different from the first color light and having the same size as the first pixel and a non-display area located around the display area, the non-display area including a first area adjacent to one side of the display area and a second area adjacent to the other side opposite the one side of the display area. The first area is arranged with a first deposition pattern containing the first deposition material and a second deposition pattern containing the second deposition material having the same size as the first deposition pattern, the second area is arranged with the second deposition pattern. The first deposition pattern is not arranged in the second area.

### BRIEF DESCRIPTION OF DRAWINGS

FIG. 1 is a schematic plan view of a display device according to an embodiment of the present disclosure.

FIG. 2 is a schematic plan view of a deposition mask unit.

FIG. 3 is a diagram illustrating a step of forming a first deposition pattern and a second deposition pattern in a manufacturing process of a display device according to an embodiment.

FIG. 4 is a diagram for explaining a step of forming a first deposition pattern and a second deposition pattern.

FIG. 5 is a diagram showing a first deposition pattern, a second deposition pattern, and a deposition pattern of a third pixel formed in a manufacturing process of a display device according to an embodiment.

FIG. 6 is a diagram for explaining a step of forming a first deposition pattern and a second deposition pattern in a manufacturing process of a display device according to an embodiment.

FIG. 7 is a diagram for explaining a step of forming a first deposition pattern and a second deposition pattern in a manufacturing process of a display device according to an embodiment.

FIG. 8 is a diagram showing a first deposition pattern, a second deposition pattern, and a deposition pattern of a third pixel formed in a manufacturing process of a display device according to an embodiment.

FIG. 9 is a schematic plan view of display device according to an embodiment of the present disclosure.

FIG. 10 is a diagram showing a first deposition pattern, a second deposition pattern, and a deposition pattern of a third pixel formed in a manufacturing process of a display device according to an embodiment.

FIG. 11 is a diagram showing a first deposition pattern, a second deposition pattern, and a deposition pattern of a third pixel formed in a manufacturing process of a display device according to an embodiment.

FIG. 12 is a schematic plan view of a display device according to an embodiment of the present disclosure.

FIG. 13 is a diagram showing a first deposition pattern, a second deposition pattern, and a deposition pattern of a third pixel formed in a manufacturing process of a display device according to an embodiment.

FIG. 14 is a diagram showing a first deposition pattern, a second deposition pattern, and a deposition pattern of a third pixel formed in a manufacturing process of a display device according to an embodiment.

FIG. 15 is a schematic plan view of a display device according to a modification of a present disclosure.

FIG. 16 is a diagram showing a first deposition pattern, a second deposition pattern, and a deposition pattern of a third pixel formed in a manufacturing process of a display device according to a modification.

FIG. 17 is a diagram for explaining a step of forming a first deposition pattern and a second deposition pattern in a manufacturing process of a display device according to a modification.

FIG. 18 is a diagram for explaining a step of forming a first deposition pattern and a second deposition pattern in a manufacturing process of a display device according to a modification.

FIG. 19 is a diagram for explaining a step of forming a first deposition pattern and a second deposition pattern in a manufacturing process of a display device according to a modification.

FIG. 20 is a diagram showing a first deposition pattern, a second deposition pattern, and a deposition pattern of a third pixel formed in a manufacturing process of a display device according to a modification.

FIG. 21 is a diagram for explaining a step of forming a first deposition pattern and a second deposition pattern in a manufacturing process of a display device according to a modification.

FIG. 22 is a diagram for explaining a step of forming a first deposition pattern and a second deposition pattern in a manufacturing process of a display device according to a modification.

FIG. 23 is a diagram for explaining a step of forming a first deposition pattern and a second deposition pattern in a manufacturing process of a display device according to a modification.

### DESCRIPTION OF EMBODIMENTS

In a manufacturing process of a display device, an inspection TEG (Test Element Group) for detecting a deposition deviation in a deposition process is formed. In the prior art described above, when forming the inspection TEG, there is a problem that the inspection of the deposition deviation of the sub-pixel cannot be performed because two or more sub-pixels are formed in an inspection area of one sub-pixel depending on the size and shape of the sub-pixel.

According to the present disclosure, it is possible to reduce manufacturing costs and provide an inexpensive organic EL display device.

Hereinafter, embodiments of the present invention will be described with reference to the drawings and the like. However, the present invention can be implemented in many different aspects, and should not be construed as being limited to the description of the embodiments exemplified below. Although the width, thickness, shape, and the like of each part are schematically represented in comparison with the actual embodiments in order to clarify the description, the drawings are merely examples and do not limit the interpretation of the present invention. In addition, in the present specification and the drawings, the same symbols (or numbers followed by a, b, A, B, and the like) are given to elements similar to those described above with respect to the above-mentioned figures, and detailed description thereof may be omitted as appropriate. Furthermore, the words labeled “first” and “second” with respect to the respective elements are convenient signs used to distinguish the respective elements, and do not have any further meaning unless otherwise specified.

In this specification, a member or area is “on (or under)” another member or area, including, without limitation, when it is directly on (or under) the other member or area, but also when it is above (or below) the other member or area, i.e., when another component is included between above (or below) the other member or area.

In this specification, the expressions “a includes A, B, or C”, “a includes any of A, B, and C”, and “a includes one selected from a group consisting of A, B, and C” do not exclude the case where a includes a plurality of combinations of A to C unless otherwise specified. Furthermore, these expressions do not exclude the case where a includes other elements.

### First Embodiment

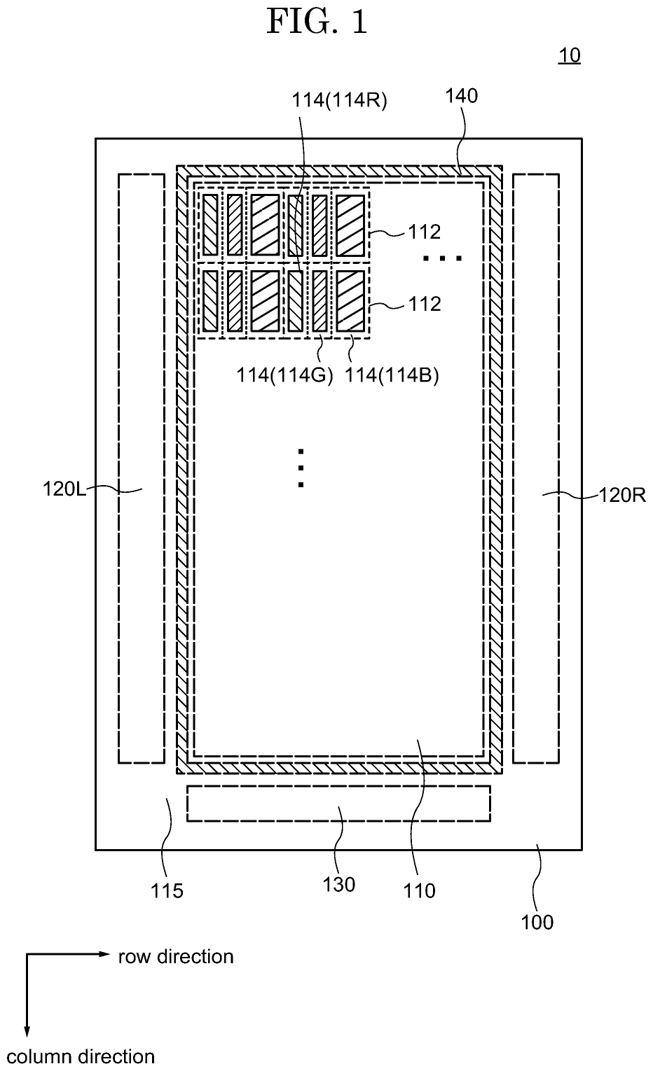

A display device 10 according to a first embodiment of the present disclosure will be described with reference to FIG. 1 to FIG. 5.

### [Display Device Configuration]

FIG. 1 is a schematic plan view of the display device 10 according to the first embodiment of the present disclosure. As shown in FIG. 1, the display device 10 includes a substrate 100. The substrate 100 is a circuit substrate arranged with various circuits. In addition, the substrate 100 includes a display area 110 and a non-display area 115. The display area 110 is arranged in a central portion of the circuit substrate 100. The non-display area 115 surrounds the display area 110. The non-display area 115 includes a first circuit area 120L, a second circuit area 120R, and a connection part 130. The non-display area 115 includes a dummy area 140. In other words, the first circuit area 120L, the second circuit area 120R, the connection part 130, and the dummy area 140 are located outside the display area 110.

In the present embodiment, in a plan view, the dummy area 140 is located between the display area 110 and the first circuit area 120L and the second circuit area 120R, and is arranged so as to surround the display area 110. However, the position of the dummy area 140 is not limited to this. The dummy area 140 is located between the display area 110 and the first circuit area 120L or the second circuit area 120R, and is arranged in at least part of the area surrounding the display area 110. For example, the dummy area 140 may be arranged between the display area 110 and the first circuit area 120L and/or between the display area 110 and the second circuit area 120R.

The display area 110 includes a plurality of pixel parts 112. In the display area 110, the plurality of pixel parts 112 is arranged in a matrix. Each of the plurality of pixel parts 112 may include three pixels 114. Each of the three pixels 114 may be a first pixel 114R that emits red light, a second pixel 114G that emits green light, or a third pixel 114B that emits blue light. Hereinafter, when the first pixel 114R, the second pixel 114G, and the third pixel 114B are not particularly distinguished from each other, they will be referred to as the pixel 114.

For example, the first pixel 114R, the second pixel 114G, and the third pixel 114B may be arranged in a stripe array in the display area 110. FIG. 1 shows an example in which the first pixel 114R and the second pixel 114G have the same size, and a width of the third pixel 114B in a row direction is relatively larger than widths of the first pixel 114R and the second pixel 114G in the row direction. However, if the size of the first pixel 114R and the size of the second pixel 114G are the same, the size and shape of the pixel 114 are not limited to this.

Each pixel 114 includes an organic EL element. The organic EL element includes an organic EL layer. The organic EL layer is formed above the substrate 100 using a deposition mask. In addition, a pixel circuit for controlling the light emission of each pixel 114 is provided with each pixel 114. The pixel circuit is comprised of a transistor, a capacitive element, or the like.

The non-display area 115 is arranged with one or more deposition patterns. The one or more deposition patterns may be arranged in at least part of the dummy area 140. In addition, one or more pseudo pixels having a layout structure similar to the pixel part 112 may be arranged in the dummy area 140. Arranging the pseudo pixel in the dummy area 140 makes it possible to create a condition as if the pixel part 112 located on the outermost periphery of the display area 110 is present in the dummy area 140. Therefore, the electrostatic breakdown occurring in the pixel part 112 located on the outermost periphery of the display area 110 can be controlled to occur in the dummy area 140. Therefore, since the electrostatic breakdown does not occur in the display area 110, the display device 10 is suppressed from being defective due to the electrostatic breakdown. However, the present embodiment is not limited to this, and the pseudo pixel in the dummy area 140 may be omitted.

The first circuit area 120L and the second circuit area 120R include a driving circuit for driving transistors included in the pixel circuit of each pixel 114. For example, the driving circuit is a scanning line driving circuit (a gate driver circuit), a signal line driving circuit (a source driver circuit) or the like. In addition, in FIG. 1, although two circuit areas of the first circuit area 120L and the second circuit area 120R are arranged, the number of circuit areas may be one or three or more.

### [Configuration of Deposition Mask]

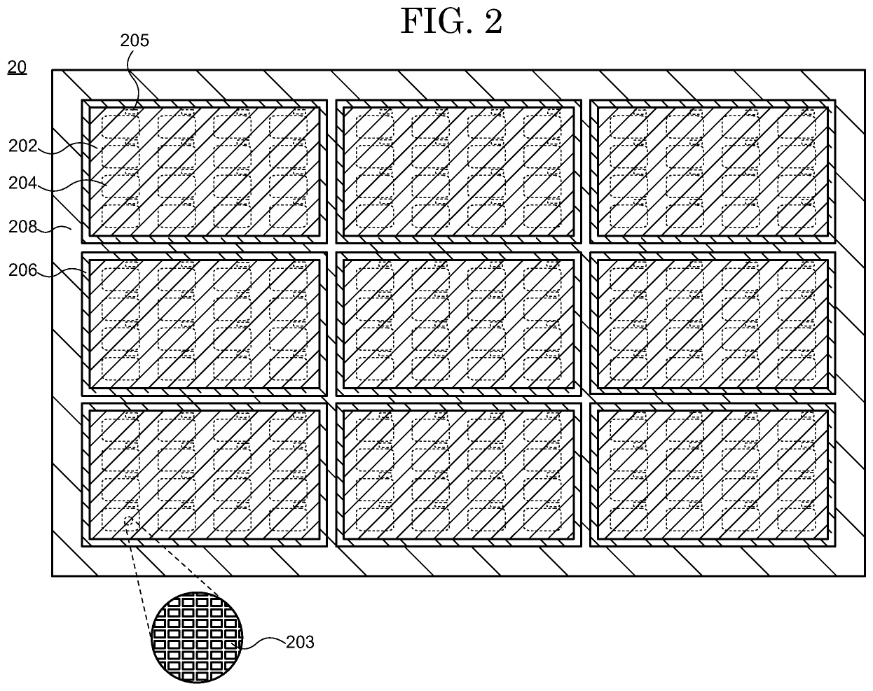

FIG. 2 is a schematic plan view of a deposition mask unit 20. The configuration of the deposition mask unit 20 shown in FIG. 2 is an example, and the configuration of the deposition mask unit 20 is not limited to the configuration shown in FIG. 2.

As shown in FIG. 2, the deposition mask unit 20 includes at least one deposition mask 202, a support frame 208 surrounding the at least one deposition mask 202, and a connection part 206 connecting the support frame 208 and the at least one deposition mask 202. In the embodiment shown in FIG. 2, a plurality of deposition masks 202 is fixed to the support frame 208 via the connection part 206, respectively.

As shown in an inset enlarged view of FIG. 2, the deposition mask 202 has a plurality of openings 203. In the deposition mask 202, the plurality of openings 203 is arranged in a predetermined area to form one mask pattern 204. The deposition mask 202 may include a plurality of mask patterns 204. The deposition mask 202 is connected to the connection part 206 in an area where the mask pattern 204 is not formed, and is held by the support frame 208.

The deposition mask 202 is a plate-shaped member, and the openings 203 are through holes that penetrate the plate-shaped member. The deposition mask 202 is formed using a metal material. The support frame 208 is arranged to support the deposition mask 202 in a flat plate shape. The support frame 208 may include a grid-like frame to hold the plurality of deposition masks 202. In the deposition mask unit 20, the support frame 208 may correspond to a size of a mother substrate, the mask pattern 204 may be arranged corresponding to individual display panels built into the mother substrate, and the plurality of openings 203 may be arranged corresponding to an arrangement of the pixels 114 in the display area 110 of the display panel. In addition, in the case where the pseudo pixel is arranged in the dummy area 140 of the display device 10, the plurality of openings 203 may include an opening corresponding to the pseudo pixel in the dummy area 140.

In the deposition mask 202, a TEG (Test Element Group) pattern 205 may be arranged separately from the mask pattern 204. The TEG pattern 205 is a pattern for forming the inspection TEG for detecting a positional shift of the deposition. Although not shown, the TEG pattern 205 has one or more openings (207), as in the mask pattern 204. In the deposition mask unit 20 shown in FIG. 2, the TEG pattern 205 is arranged in a one-to-one manner corresponding to one mask pattern 204. However, the present embodiment is not limited to this, and for example, one or more TEG patterns 205 may be arranged at any position of one deposition mask 202.

The connection part 206 has a function of connecting the deposition mask 202 and the support frame 208 and fixing them to each other. Therefore, although the support frame 208 is not in direct contact with the deposition mask 202, the connection part 206 is in contact with the deposition mask 202 at a non-opening part (an area where the mask pattern 204 is not formed) of the deposition mask 202 and is in contact with a side surface of the support frame 208.

In the example shown in FIG. 2, an aspect in which the plurality of deposition masks 202 is held on the support frame 208. However, an embodiment of the present invention is not limited to this, and for example, the embodiment may include a configuration in which one deposition mask 202 is held on the support frame 208 via the connection part 206.

The deposition mask unit 20 is used in a step of forming the organic EL element in the manufacturing process of the display panel. Specifically, the deposition mask unit 20 is used in a step of forming the organic EL layer including a light-emitting layer of the organic EL element using the vacuum-deposition method. In the step of forming the organic EL layer, a deposition area of the mother substrate is arranged to align with the mask pattern 204 of the deposition mask 202. A deposition material passes through the plurality of openings 203 of the mask pattern 204, and the deposition material deposits on the deposition area. The deposition material may be a luminescent material, an electron transport material, an electron injection material, a hole transport material, a hole injection material, or the like.

The deposition mask 202 and the connection part 206 are formed using a zero-valent metal material such as nickel (Ni), copper (Cu), titanium (Ti), chrome (Cr), and the like. The deposition mask 202 and the connection part 206 may have the same material composition. Similarly, the support frame 208 is formed using a zero-valent metal material such as nickel (Ni), iron (Fe), cobalt (Co), chrome (Cr), manganese (Mn), and the like. For example, the material composition of the support frame 208 may be an alloy containing iron (Fe) and chromium (Cr), or an alloy containing iron (Fe), nickel (Ni), and manganese (Mn), and the alloy may contain carbon (C).

### [Manufacturing Process of Light-Emitting Layer]

In the manufacturing process of the display device 10 according to the present embodiment, when forming the organic EL layer of each pixel 114 on the substrate 100, the same deposition mask unit 20 is used to form the first pixel 114R and the second pixel 114G. In other words, when forming the organic EL layer, the same deposition mask 202 is used for forming the first pixel 114R and the second pixel 114G. Specifically, the organic EL layer of the first pixel 114R or the second pixel 114G is formed on the substrate 100 by using the deposition mask unit 20, and then the same deposition mask unit 20 is shifted by a predetermined distance to form the organic EL layer of the second pixel 14G or the first pixel 114R. Hereinafter, the case of forming the light-emitting layer in the organic EL layer of the pixel 114 will be described as an example.

In the case of forming the light-emitting layer by the deposition process, the deposition material is the luminescent material. The light-emitting layer of the first pixel 114R is formed using a first luminescent material (first deposition material) that emits red light (first color light). The light-emitting layer of the second pixel 114G is formed using a second luminescent material (second deposition material) that emits green light (second color light). The first deposition material and the second deposition material may include a dopant material and a host material, respectively.

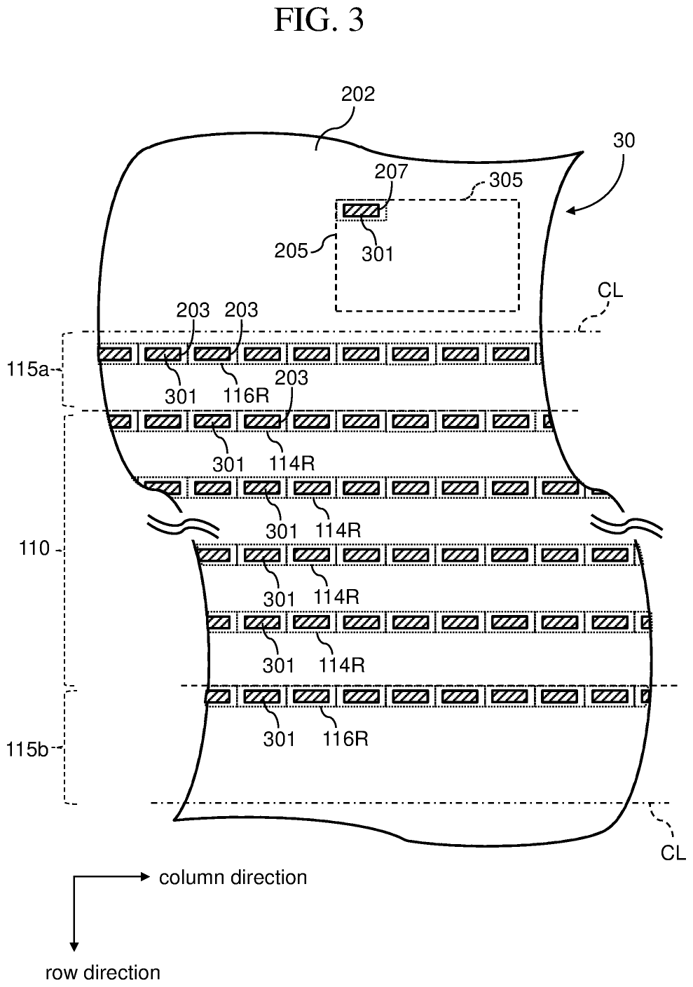

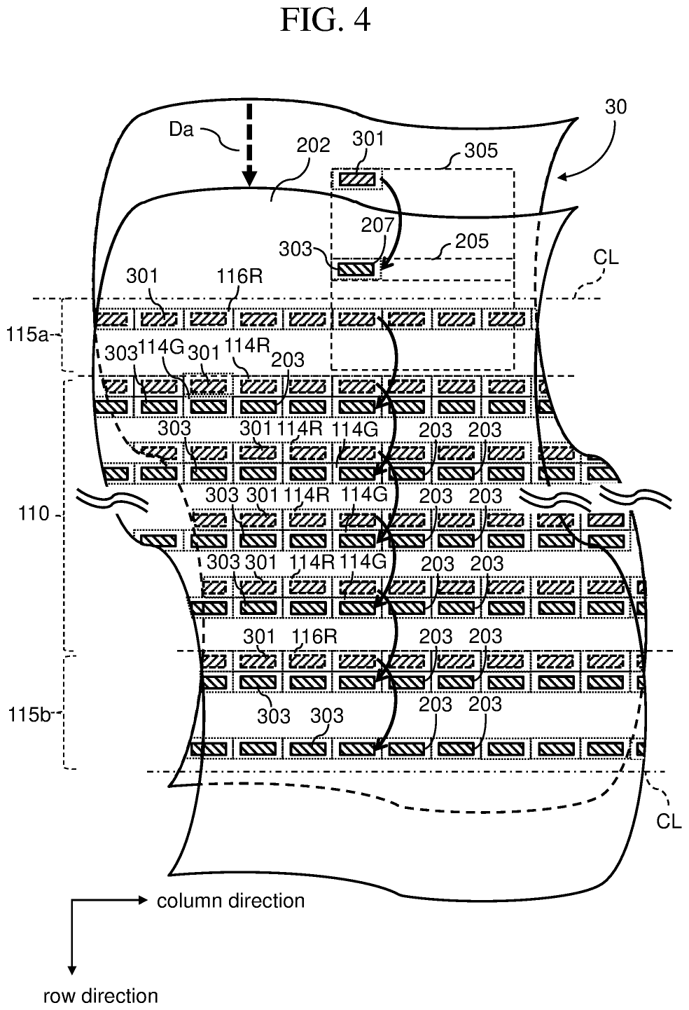

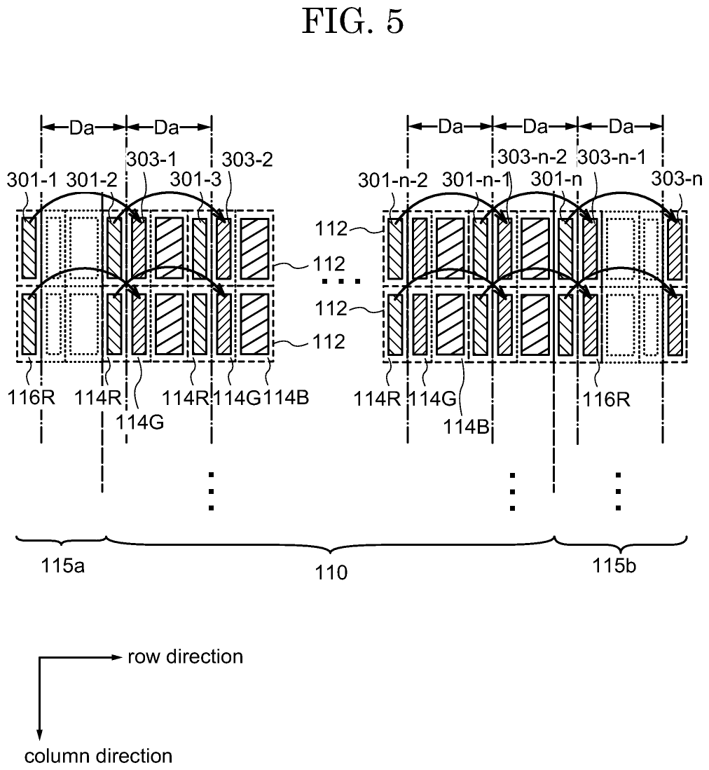

FIG. 3 and FIG. 4 are diagrams illustrating a step of forming a first deposition pattern containing the first deposition material and a step of forming a second deposition pattern containing the second deposition material in the manufacturing process of the display device 10 according to the present embodiment. FIG. 5 is a diagram showing the first deposition pattern, the second deposition pattern, and a deposition pattern of the third pixel 114B formed in the manufacturing process of the display device 10 including the step of forming the first deposition pattern and the second deposition pattern described with reference to FIG. 3 and FIG. 4. In FIG. 3 to FIG. 5, part of the display area 110 of the display device 10, part of the non-display area 115 (first area 115a) adjacent to one side of the display area 110, and part of the non-display area 115 (second area 115b) adjacent to the other side opposite the one side of the display area 110 are shown.

As shown in FIG. 3, the deposition mask 202 is arranged above a mother substrate 30, and the first deposition material, which is the first luminescent material, is deposited on the mother substrate 30 to have a predetermined thickness in alignment with the opening 203 of the deposition mask 202, thereby forming a first deposition pattern 301.

In this step, the first deposition pattern 301 is formed not only in an area corresponding to the display area 110 of the display device 10 but also in at least part of the first area 115a and the second area 115b adjacent to one side and the other side of the display area 110. In the case where the display device 10 includes the dummy area 140, a light-emitting layer of the pseudo pixel 116R may be formed in the first area 115a and the second area 115b. In this case, the first deposition pattern 301 corresponding to the light-emitting layer of the pseudo pixel 116R is formed in the first area 115a and the second area 115b. In the present embodiment, the case where the light-emitting layer of the pseudo pixel 116R contains the first luminescent material (the first deposition material) will be described as an example.

In addition, the first deposition pattern 301 is formed in alignment with the opening 207 of the TEG pattern 205. The first deposition pattern 301 formed in alignment with the TEG pattern 205 is arranged in a TEG area 305 arranged outside a panel cut line CL of the mother substrate 30. The mother substrate 30 is finally cut along the panel cut line CL, and the individual display panels are separated from the mother substrate 30. In FIG. 3, the display area 110 and the non-display area 115 (the first area 115a and the second area 115b) inside the upper and lower panel cut lines CL are separated from the mother substrate 30 as the display panel. On the other hand, the TEG area 305 arranged outside the panel cut line CL is not included in the display panel. In addition, the panel cut line CL is arranged along the shapes of the individual display panels built into the mother substrate 30. Although not shown in FIG. 3, when the display panel is rectangular, the panel cut line CL is further arranged along a direction orthogonal to the upper and lower panel cut lines CL in addition to the upper and lower panel cut lines CL shown in FIG. 3.

After the first deposition pattern 301 is formed, the second deposition material, which is the second luminescent material, is deposited on the mother substrate 30 to have a predetermined thickness in alignment with the opening 203 of the deposition mask 202 using the deposition mask 202 used to form the first deposition pattern 301, thereby forming a second deposition pattern 303.

As shown in FIG. 4, when forming the second deposition pattern 303, the deposition mask 202 is shifted by a predetermined distance Da from a position arranged to form the first deposition pattern 301. The deposition mask 202 may be shifted by the predetermined distance Da in the row direction of the pixel 114. For example, the opening 203 of the deposition mask 202 used to form the first deposition pattern 301 in the first area 115a is used to form the second deposition pattern 303, which is in the same pixel row in the display area 110 and separated by the distance Da, and is closest to the one side of the display area 110.

The predetermined distance Da may be a distance of three pixels. The “three pixels” corresponds to the number of pixels 114 (the first pixel 114R, the second pixel 114G, and the third pixel 114B), and does not depend on the size of each of the first pixel 114R, the second pixel 114G, and the third pixel 114B. In the present embodiment, the predetermined distance Da indicates the number of pixels 114 in the row direction. Specifically, the first deposition pattern 301 in the first area 115a and the second deposition pattern 303 in the display area, which is closest to the one side of the display area 110, are separated by three pixels.

In FIG. 5, the same number (1, 2, 3 . . . n, n is a natural number) is added after the symbols of the first deposition pattern 301 and the second deposition pattern 303 present in the same pixel row and formed using the same opening 203 of the deposition mask 202. As described above, a first deposition pattern 301-1 of the pseudo pixel 116R in the first area 115a and a second deposition pattern 303-1 in the display area 110, which is closest to the one side of the display area 110, are formed using the same opening 203 of the deposition mask 202. Similarly, a first deposition pattern 301-2 in the display area, which is closest to the one side of the display area 110, and a second deposition pattern 303-2 are formed using the same opening 203 of the deposition mask 202.

Similarly, a first deposition pattern 301-n−1 in the display area 110, which is closest to the other side of the display area 110, and a second deposition pattern 303-n−1 in the second area 115b, which is closest to the other side of the display area 110, are formed using the same opening 203 of the deposition mask 202, and a first deposition pattern 301-n of the pseudo pixel 116R in the second area 115b and a second deposition pattern 303-n in the second area 115b are formed using the same opening 203 of the deposition mask 202.

As shown in FIG. 5, although the first deposition pattern 301-1 is arranged in the first area 115a, the second deposition pattern 303 is not arranged in the first area 115a. On the other hand, the first deposition pattern 301-n and the second deposition patterns 303-n−1 and 303-n are arranged in the second area 115b. In addition, the second deposition pattern 303 is formed more than the first deposition pattern 301 in the second area 115b.

As shown in FIG. 4, when the second deposition pattern 303 is formed in the display area 110 and the second area 115b, the second deposition pattern 303 is also formed in the TEG area 305 of the mother substrate 30 in alignment with the opening 207 of the TEG pattern 205. The first deposition pattern 301 and the second deposition pattern 303 formed in the TEG area 305 are separated by three pixels in the row direction.

As described above, after the first deposition pattern 301 is formed, the second deposition pattern 303 is formed by shifting the deposition mask 202 by the predetermined distance Da and, in the present embodiment, by the distance of three pixels in the row direction, whereby the light-emitting layers of the first pixel 114R and the second pixel 114G can be formed using the same deposition mask 202. In addition, since the deposition mask 202 is shifted by the distance of three pixels, two or more inspection TEGs are not formed in an area (an inspection area) where one inspection TEG is located in the TEG area 305. Therefore, it is possible to inspect the pattern deviation of the deposition pattern. Therefore, according to the present embodiment, it is possible to improve the reliability of the display device 10 while reducing the manufacturing cost of the display device 10 by using the same deposition mask 202 for the first pixel 114R and the second pixel 114G.

### Second Embodiment

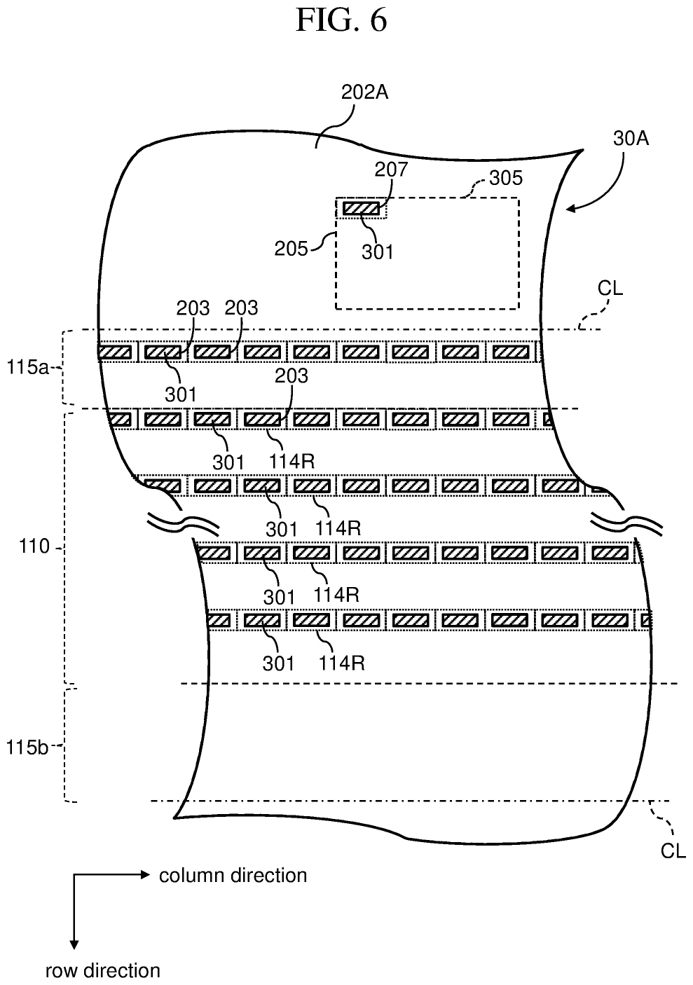

A display device 10A according to a second embodiment will be described with reference to FIG. 6 to FIG. 8.

Since a configuration of the display device 10A is substantially the same as that of the display device 10 according to the first embodiment, except that no dummy area is arranged, a detailed explanation will be omitted. Hereinafter, the configuration of the display device 10A, which is different from the display device 10 according to the first embodiment, will be mainly described.

In the display device 10 according to the first embodiment, the non-display area 115 includes the dummy area 140 where the pseudo pixel is arranged. On the other hand, the display device 10A according to the present embodiment does not include the dummy area 140 in the non-display area 115.

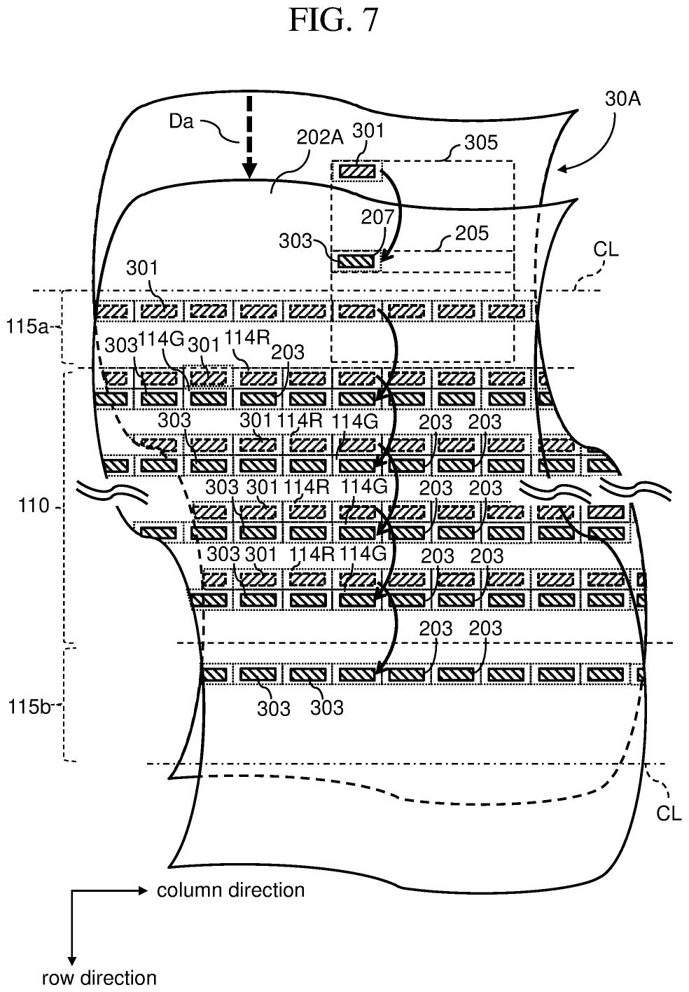

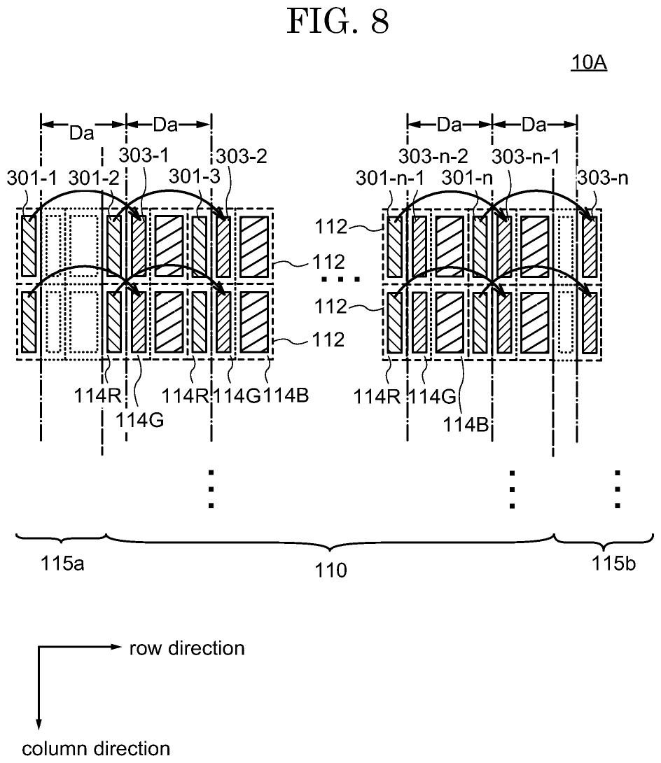

FIG. 6 and FIG. 7 are diagrams illustrating a step of forming the first deposition pattern 301 and the second deposition pattern 303 in a manufacturing process of the display device 10A according to the present embodiment. FIG. 8 is a diagram showing the first deposition pattern 301, the second deposition pattern 303, and the deposition pattern of the third pixel 114B formed in a manufacturing process of the display device 10A according to the present embodiment. In FIG. 6 to FIG. 8, part of a display area 110 of the display device 10A, part of the non-display area 115 (a first area 115a) adjacent to one side of the display area 110, and part of the non-display area 115 (second area 115b) adjacent to the other side opposite the one side of the display area 110 are shown.

As shown in FIG. 6, a deposition mask 202A is arranged above a mother substrate 30A, and the first deposition material, which is the first luminescent material, is deposited on the mother substrate 30 to have a predetermined thickness in alignment with the opening 203 of the deposition mask 202A, thereby forming the first deposition pattern 301.

In this step, the first deposition pattern 301 is formed not only in the area corresponding to the display area 110 of the display device 10A but also in at least part of the first area 115a adjacent to one side of the display area 110. In the present embodiment, the dummy area where the pseudo pixel is arranged is not included in the non-display area 115. Therefore, the deposition pattern 301 formed in the first area 115a is a dummy deposition pattern that does not contribute to the configuration of the pixel.

In addition, the first deposition pattern 301 is formed in alignment with the opening 207 of the TEG pattern 205. The first deposition pattern 301 formed in alignment with the TEG pattern 205 is arranged in the TEG area 305 arranged outside the panel cut line CL of the mother substrate 30A.

After the first deposition pattern 301 is formed, the second deposition material, which is the second luminescent material, is deposited on the mother substrate 30A to have a predetermined thickness in alignment with the opening 203 of the deposition mask 202A using the deposition mask 202A used to form the first deposition pattern 301, thereby forming the second deposition pattern 303.

Similar to the step of forming the second deposition pattern 303 in the first embodiment described with reference to FIG. 4, in the present embodiment as well, when forming the second deposition pattern 303, the deposition mask 202A is shifted by a predetermined Da from the position arranged for forming the first deposition pattern 301. For example, as shown in FIG. 7, the deposition mask 202A may be shifted by the predetermined distance Da in the row direction of the pixel 114.

The predetermined distance Da may be the distance of three pixels. In other words, the first deposition pattern 301 in the first area 115a and the second deposition pattern 303 in the display area 110, which is closest to the one side of the display area 110, are separated by three pixels.

In FIG. 8, the same number (1, 2, 3 . . . n, n is a natural number) is added after the symbols of the first deposition pattern 301 and the second deposition pattern 303 present in the same pixel row and formed using the same opening 203 of the deposition mask 202A. The first deposition pattern 301-1 in the first area 115a and the second deposition pattern 303-1 in the display area 110, which is closest to the one side of the display area 110, are formed using the same opening 203 of the deposition mask 202. Similarly, the first deposition pattern 301-2 in the display area 110, which is closest to the one side of the display area 110, and the second deposition pattern 303-2 are formed using the same opening 203 of the deposition mask 202.

Similarly, the first deposition pattern 301-n in the display area 110, which is closest to the other side of the display area 110, and the second deposition pattern 303-n in the second area 115b, which is closest to the other side of the display area 110, are formed using the same opening 203 of the deposition mask 202.

As shown in FIG. 8, although the first deposition pattern 301-1 is arranged in the first area 115a, the second deposition pattern 303 is not arranged in the first area 115a. In addition, unlike the first embodiment, in the present embodiment, although the second deposition pattern 303-n is arranged in the second area 115b, the first deposition pattern 301 is not arranged in the second area 115b.

Also in the present embodiment, as shown in FIG. 7, when the second deposition pattern 303 is formed in the display area 110, the second deposition pattern 303 is also formed in the TEG area 305 of the mother substrate 30A in alignment with the opening 207 of the TEG pattern 205. The first deposition pattern 301 and the second deposition pattern 303 formed in the TEG area 305 are separated by three pixels in the row direction.

As described above, even when there is no dummy area 140 in the non-display area 115, the first deposition pattern 301 is formed in the non-display area 115 in addition to the display area 110, and thereafter, the second deposition pattern 303 is formed by shifting the deposition mask 202A by the predetermined distance Da and, in the present embodiment, by the distance of three pixels in the row direction, whereby the light-emitting layers of the first pixel 114R and the second pixel 114G can be formed using the same deposition mask 202A. In addition, since the deposition mask 202A is shifted by the distance of three pixels, two or more inspection TEGs are not formed in an area (an inspection area) where one inspection TEG is located in the TEG area 305. Therefore, it is possible to inspect the pattern deviation of the deposition pattern. Therefore, similar to the first embodiment, also according to the present embodiment, it is possible to improve the reliability of the display device 10A while reducing the manufacturing cost of the display device 10A by using the same deposition mask 202A for the first pixel 114R and the second pixel 114G.

### Third Embodiment

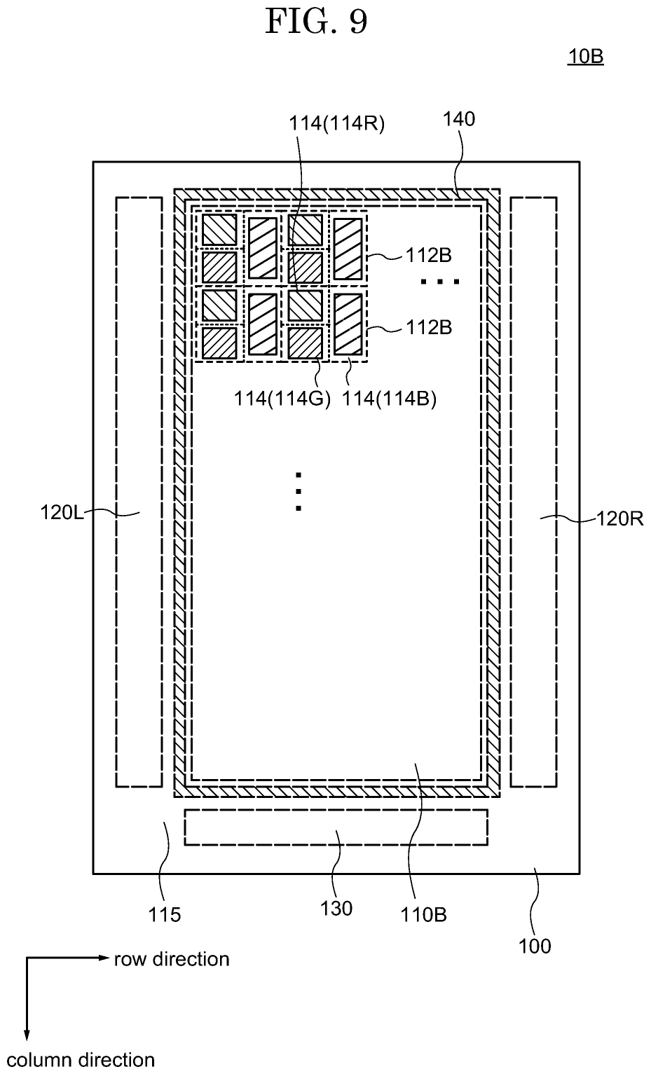

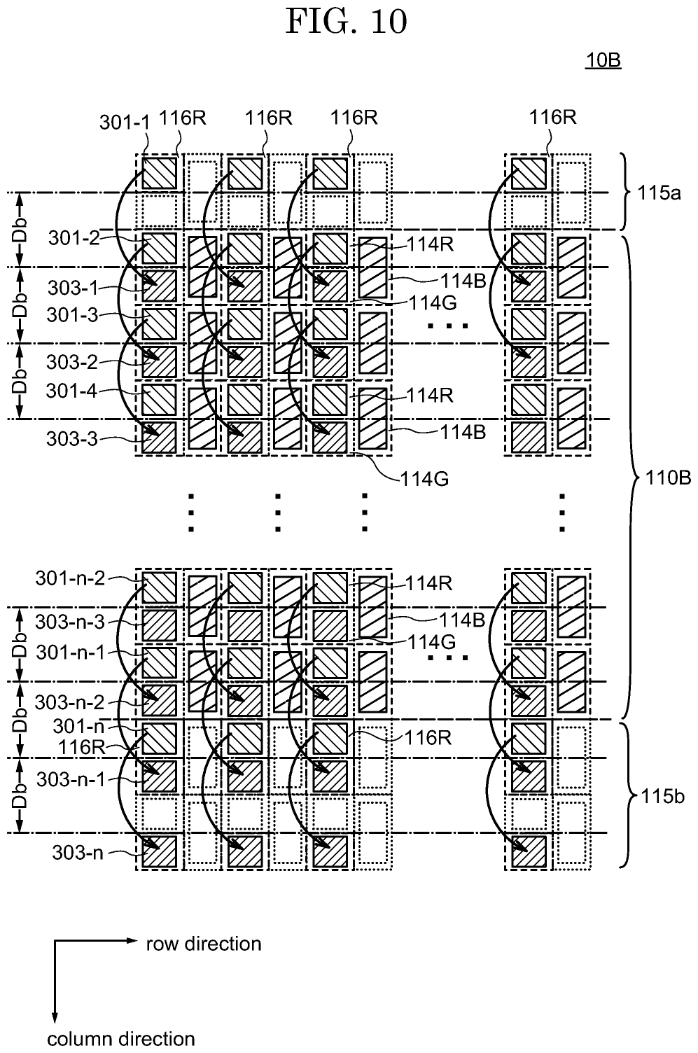

In the first embodiment and the second embodiment described above, the case where the pixels 114 arranged in the display area 110 of the display devices 10 and 10A are arranged in a stripe array is described. However, in the present disclosure, the arrangement of the pixels 114 is not limited to the stripe array. A display device 10B according to a third embodiment will be described below with reference to FIG. 9 to FIG. 10.

FIG. 9 is a schematic plan view of the display device 10B according to the third embodiment of the present disclosure. As shown in FIG. 9, since a configuration of the display device 10B is substantially the same as that of the display device 10 according to the first embodiment except for the arrangement of the pixels 114, a detailed explanation will be omitted. Hereinafter, the configuration of the display device 10B, which is different from the display device 10 according to the first embodiment, will be mainly described.

A display area 110B of the display device 10B includes a plurality of pixel parts 112B. In the display area 110B, the plurality of pixel parts 112B is arranged in a matrix. Each of the plurality of pixel parts 112B may include three pixels 114. Each of the three pixels 114 may be the first pixel 114R that emits red light, the second pixel 114G that emits green light, or the third pixel 114B that emits blue light. Hereinafter, when the first pixel 114R, the second pixel 114G, and the third pixel 114B are not particularly distinguished from each other, they will be referred to as the pixel 114.

As shown in FIG. 9, in one pixel part 112B, the first pixel 114R, the second pixel 114G, and the third pixel 114B are arranged such that the first pixel 114R and the second pixel 114G are arranged adjacent to each other in the column direction, and the third pixel 114B is arranged adjacent to the first pixel part 114R and the second pixel 114G in the row direction. That is, the arrangement of the first pixel 114R, the second pixel 114G, and the third pixel 114B is a so-called S-stripe array. The size and shape of the pixels 114 are not particularly limited as long as the first pixel 114R and the second pixel 114G are the same size.

In the display area 110B of the display device 10B, the first pixel 114R and the second pixel 114G can be formed using the same deposition mask as in the first embodiment and the second embodiment described above.

FIG. 10 is a diagram showing the first deposition pattern 301, the second deposition pattern 303, and the deposition pattern of the third pixel 114B formed in the manufacturing process of the display device 10B according to the present embodiment. In FIG. 10, part of the display area 110B of the display device 10B, part of the non-display area 115 (a first area 115a) adjacent to one side of the display area 110B, and part of the non-display area 115 (a second area 115b) adjacent to the other side opposite the one side of the display area 110B are shown. In the present embodiment, the case where the dummy area 140 where the pseudo pixel 116 is arranged is arranged in the non-display area 115 of the display device 10B will be described.

Although not shown, similar to the step of forming the second deposition pattern 303 of the first embodiment and the second embodiment described above, also in the present embodiment, after the first deposition pattern 301 is formed on the mother substrate by using the deposition mask, the second deposition pattern 303 can be formed by shifting the same deposition mask by a predetermined db from the position arranged to form the first deposition pattern 301. In the present embodiment, the deposition mask may be shifted by the predetermined distance db in the column direction of the pixel 114. The predetermined distance db may be a distance of two pixels. In other words, the first deposition pattern 301 and the second deposition pattern 303 formed using the same opening of the deposition mask are separated by two pixels in the column direction.

In FIG. 10, the same number (1, 2, 3 . . . n, n is a natural number) is added after the symbols of the first deposition pattern 301 and the second deposition pattern 303 present in the same pixel column and formed using the same opening 203 of the deposition mask. The first deposition pattern 301-1 of the pseudo pixel 116R in the first area 115a and the second deposition pattern 303-1 in the display area 1106, which is closest to the one side of the display area 1106, are formed using the same opening 203 of the deposition mask. Similarly, the first deposition pattern 301-2 in the display area 1106, which is closest to the one side of the display area 1106, and the second deposition pattern 303-2 are formed using the same opening 203 of the deposition mask.

Similarly, the first deposition pattern 301-n−1 in the display area 1106, which is closest to the other side of the display area 1106, and the second deposition pattern 303-n−1 in the second area 115b, which is closest to the other side of the display area 1106, are formed using the same opening 203 of the deposition mask, and the first deposition pattern 301-n of the pseudo pixel 116R in the second area 115b and the second deposition pattern 303-n in the second area 115b are formed using the same opening 203 of the deposition mask 202.

As shown in FIG. 10, although the first deposition pattern 301-1 is arranged in the first area 115a, the second deposition pattern 303 is not arranged in the first area 115a. On the other hand, the first deposition pattern 301-n and the second deposition patterns 303-n−1 and 303-n are arranged in the second area 115b. In addition, the second deposition pattern 303 is formed more than the first deposition pattern 301 in the second area 115b.

Although not shown, when the first deposition pattern 301 and the second deposition pattern 303 are formed in the display area 110B and in at least part of the non-display area 115, the first deposition pattern 301 and the second deposition pattern 303 are formed in the TEG area in the mother substrate in alignment with the opening of the TEG pattern. The first deposition pattern 301 and the second deposition pattern 303 formed in the TEG area are separated by two pixels in the column direction.

As described above, in the manufacturing process of the display device 10B having the pixels 114 in the S-stripe array, after the first deposition pattern 301 is formed, the second deposition pattern 303 is formed by shifting the deposition mask by a distance of two pixels in the column direction, whereby the light-emitting layers of the first pixel 114R and the second pixel 114G can be formed using the same deposition mask. In addition, since the deposition mask is shifted by a distance of two pixels, two or more inspection TEGs are not formed in an area (an inspection area) where one inspection TEG is located in the TEG area. Therefore, it is possible to inspect the pattern deviation of the deposition pattern. Therefore, according to the present embodiment, it is possible to improve the reliability of the display device 10B while reducing the manufacturing cost of the display device 10B by using the same deposition mask for the first pixel 114R and the second pixel 114G.

### Fourth Embodiment

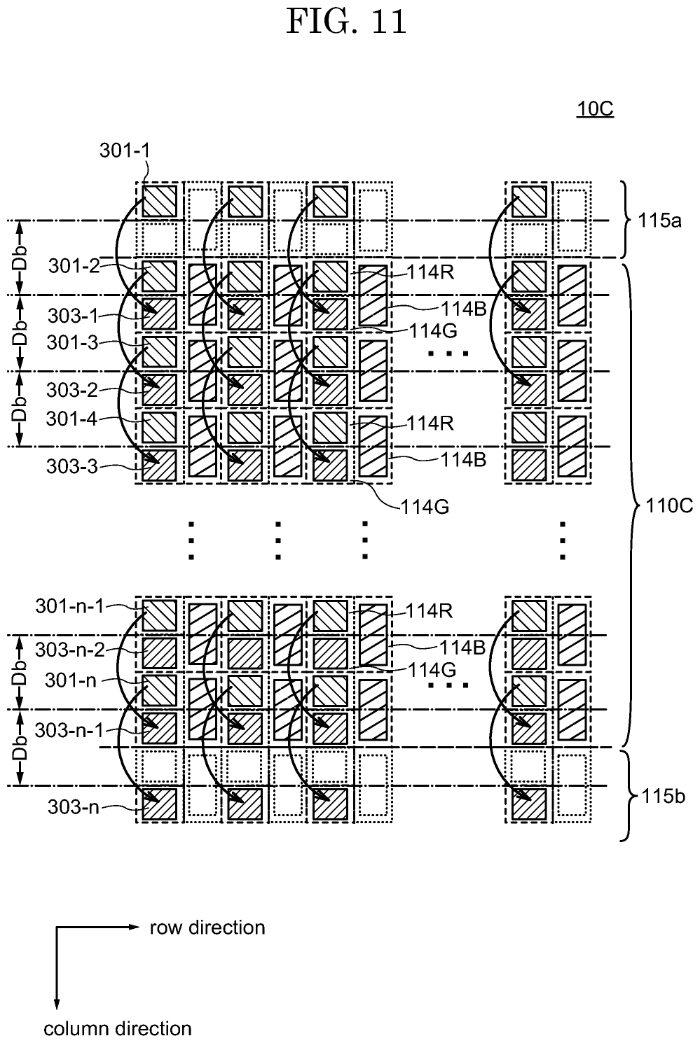

A display device 10C according to a fourth embodiment will be described with reference to FIG. 11.

Since a configuration of the display device 10C is substantially the same as that of the display device 10B according to the third embodiment except that no dummy area is arranged, a detailed explanation will be omitted. Hereinafter, the configuration of the display device 10C, which is different from the display device 10B according to the third embodiment, will be mainly described.

In the display device 10B according to the third embodiment, the non-display area 115 includes the dummy area 140 where the pseudo pixel is arranged. On the other hand, the display device 10C according to the present embodiment does not include the dummy area 140 in the non-display area 115.

FIG. 11 is a diagram showing the first deposition pattern 301, the second deposition pattern 303, and the deposition pattern of the third pixel 114B formed in the manufacturing process of the display device 10C according to the present embodiment. In FIG. 11, part of a display area 110C of the display device 10C, part of the non-display area 115 (a first area 115a) adjacent to one side of the display area 110C, and part of the non-display area 115 (second area 115b) adjacent to the other side opposite the one side of the display area 110C are shown.

Although not shown, similar to the third embodiment described above, in the present embodiment as well, after the first deposition pattern 301 is formed on the mother substrate by using the deposition mask, the same deposition mask is moved by a distance of two pixels from the position where the same deposition mask is arranged to form the first deposition pattern 301 toward the column direction of the pixel 114 to form the second deposition pattern 303. In other words, the first deposition pattern 301 and the second deposition pattern 303 formed using the same opening of the deposition mask are separated by two pixels in the column direction.

The first deposition pattern 301 may be formed not only in an area corresponding to the display area 110C of the display device 10C but also in at least part of the first area 115a adjacent to one side of the display area 110C. In the present embodiment, the dummy area where the pseudo pixel is arranged is not included in the non-display area 115. Therefore, the deposition pattern 301 formed in the first area 115a is the dummy deposition pattern that does not contribute to the configuration of the pixel.

In FIG. 11, the same number (1, 2, 3 . . . n, n is a natural number) is added after the symbols of the first deposition pattern 301 and the second deposition pattern 303 present in the same pixel column and formed using the same opening 203 of the deposition mask. The first deposition pattern 301-1 in the first area 115a and the second deposition pattern 303-1 in the display area 110C, which is closest to the one side of the display area 110C, are formed using the same opening 203 of the deposition mask. Similarly, the first deposition pattern 301-2 in the display area 110C, which is closest to the one side of the display area 110C, and the second deposition pattern 303-2 are formed using the same opening 203 of the deposition mask 202.

Similarly, the first deposition pattern 301-n in the display area 110C, which is closest to the other side of the display area 110C, and the second deposition pattern 303-n in the second area 115b, which is closest to the other side of the display area 110C, are formed using the same opening 203 of the deposition mask.

As shown in FIG. 11, although the first deposition pattern 301-1 is arranged in the first area 115a, the second deposition pattern 303 is not arranged in the first area 115a. In addition, unlike the third embodiment, in the present embodiment, although the second deposition pattern 303-n is arranged in the second area 115b, the first deposition pattern 301 is not arranged in the second area 115b.

Although not shown, when the first deposition pattern 301 and the second deposition pattern 303 are formed in the display area 1108 and in at least part of the non-display area 115, the first deposition pattern 301 and the second deposition pattern 303 are formed in the TEG area in the mother substrate in alignment with the opening of the TEG pattern. The first deposition pattern 301 and the second deposition pattern 303 formed in the TEG area are separated by two pixels in the column direction.

As described above, even when there is no dummy area 140 in the non-display area 115, the first deposition pattern 301 is formed in the non-display area 115 in addition to the display area 110C, and thereafter, the second deposition pattern 303 is formed by shifting the deposition mask by the predetermined distance db, in the present embodiment, by a distance of two pixels in the column direction, whereby the light-emitting layers of the first pixel 114R and the second pixel 114G can be formed using the same deposition mask. In addition, since the deposition mask is shifted by two pixels, two or more inspection TEGs are not formed in an area (an inspection area) where one inspection TEG is located in the TEG area. Therefore, it is possible to inspect the pattern deviation of the deposition pattern. Therefore, similar to the third embodiment, also in the present embodiment, it is possible to improve the reliability of the display device 10C while reducing the manufacturing cost of the display device 10C by using the same deposition mask for the first pixel 114R and the second pixel 114G.

### Fifth Embodiment

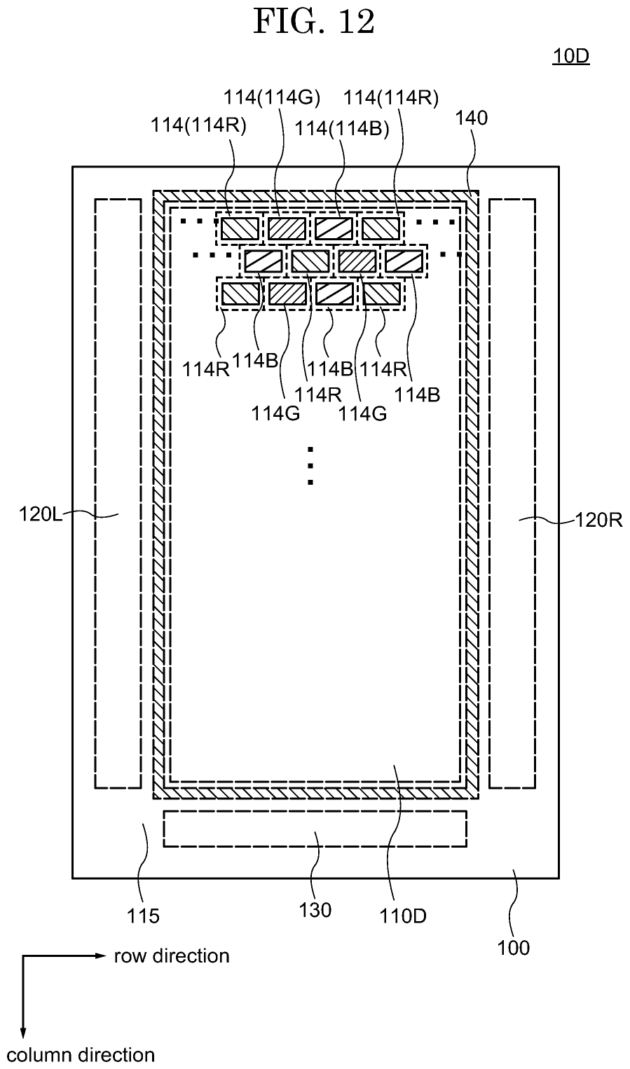

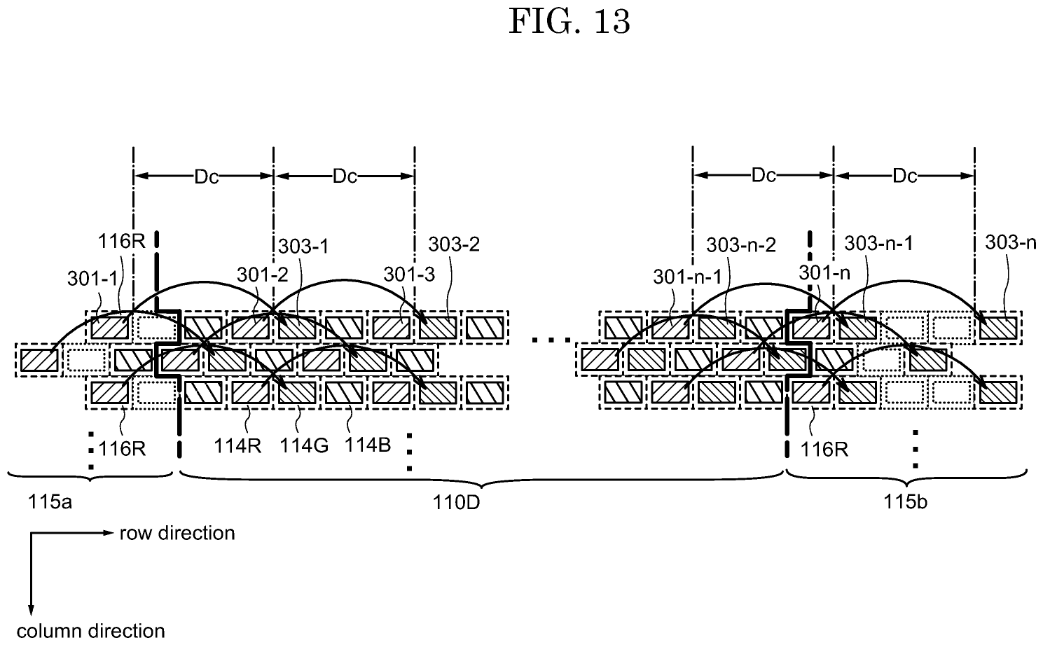

A display device 10D according to a fifth embodiment will be described below with reference to FIG. 12 to FIG. 13.

FIG. 12 is a schematic plan view of the display device 10D according to the fifth embodiment of the present disclosure. As shown in FIG. 12, since a configuration of the display device 10D is substantially the same as that of the display device 10 according to the first embodiment except for the arrangement of the pixels 114, a detailed explanation will be omitted. Hereinafter, a configuration of the display device 10D, which is different from the display device 10 according to the first embodiment, will be mainly described.

A display area 110D of the display device 10D may include the plurality of pixels 114. The plurality of pixels includes the first pixel 114R that emits red light, the second pixel 114G that emits green light, and the third pixel 114B that emits blue light. Hereinafter, when the first pixel 114R, the second pixel 114G, and the third pixel 114B are not particularly distinguished from each other, they will be referred to as the pixel 114.

As shown in FIG. 12, the first pixel 114R, the second pixel 114G, and the third pixel 114B may be in a delta array. The size and shape of the pixels 114 are not particularly limited as long as the first pixel 114R and the second pixel 114G are the same size.

In the display area 110D of the display device 10D, the first pixel 114R and the second pixel 114G can be formed using the same deposition mask as in the first to fourth embodiments described above.

FIG. 13 is a diagram showing the first deposition pattern 301, the second deposition pattern 303, and the deposition pattern of the third pixel 114B formed in the manufacturing process of the display device 10D according to the present embodiment. In FIG. 13, part of the display area 110D of the display device 10D, part of the non-display area 115 (a first area 115a) adjacent to one side of the display area 110D, and part of the non-display area 115 (second area 115b) adjacent to the other side opposite the one side of the display area 110D are shown. In the present embodiment, the case where the dummy area 140 where the pseudo pixel 116 is arranged is arranged in the non-display area 115 of the display device 10D will be described.

Although not shown, similar to the step of forming the second deposition pattern 303 of the first to fourth embodiments described above, also in the present embodiment, after the first deposition pattern 301 is formed on the mother substrate by using the deposition mask, the second deposition pattern 303 can be formed by shifting the same deposition mask by a predetermined distance Dc from the position arranged to form the first deposition pattern 301. In the present embodiment, the deposition mask may be shifted by the predetermined distance Dc in the row direction of the pixel 114. The predetermined distance db may be the distance of three pixels. In other words, the first deposition pattern 301 and the second deposition pattern 303 formed using the same opening of the deposition mask are separated by three pixels in the row direction.

In FIG. 13, the same number (1, 2, 3 . . . n, n is a natural number) is added after the symbols of the first deposition pattern 301 and the second deposition pattern 303 present in the same pixel row and are formed using the same opening 203 of the deposition mask. The first deposition pattern 301-1 of the pseudo pixel 116R in the first area 115a and the second deposition pattern 303-1 in the display area 110D, which is closest to one side of the display area 110D, are formed using the same opening 203 of the deposition mask. Similarly, the first deposition pattern 301-2 in the display are 110D, which is closest to the one side of the display area 110D, and the second deposition pattern 303-2 are formed using the same opening 203 of the deposition mask.

Similarly, the first deposition pattern 301-n−1 in the display are 110D, which is closest to the other side of the display area 110D, and the second deposition pattern 303-n−1 in the second area 115b, which is closest to the other side of the display area 110D, are formed using the same opening 203 of the deposition mask, and the first deposition pattern 301-n of the pseudo pixel 116R in the second area 115b and the second deposition pattern 303-n in the second area 115b are formed using the same opening 203 of the deposition mask.

As shown in FIG. 13, although the first deposition pattern 301-1 is arranged in the first area 115a, the second deposition pattern 303 is not arranged in the first area 115a. On the other hand, the first deposition pattern 301-n, and the second deposition patterns 303-n−1 and 303-n are arranged in the second area 115b. In addition, the second deposition pattern 303 is formed more than the first deposition pattern 301 in the second area 115b.

Although not shown, when the first deposition pattern 301 and the second deposition pattern 303 are formed in the display area 110D and in at least part of the non-display area 115, the first deposition pattern 301 and the second deposition pattern 303 are formed in the TEG area in the mother substrate in alignment with the opening of the TEG pattern. The first deposition pattern 301 and the second deposition pattern 303 formed in the TEG area are separated by three pixels in the row direction.

As described above, in the manufacturing process of the display device 10D having the pixels 114 in the delta array, after the first deposition pattern 301 is formed, the second deposition pattern 303 is formed by shifting the deposition mask by the distance of three pixels in the row direction, whereby the light-emitting layers of the first pixel 114R and the second pixel 114G can be formed using the same deposition mask. In addition, since the deposition mask is shifted by the distance of three pixels, two or more inspection TEGs are not formed in an area where one inspection TEG (an inspection area) is located in the TEG area. Therefore, it is possible to inspect the pattern deviation of the deposition pattern. Therefore, in the present embodiment, it is possible to improve the reliability of the display device 10D while reducing the manufacturing cost of the display device 10D by using the same deposition mask for the first pixel 114R and the second pixel 114G.

### Sixth Embodiment

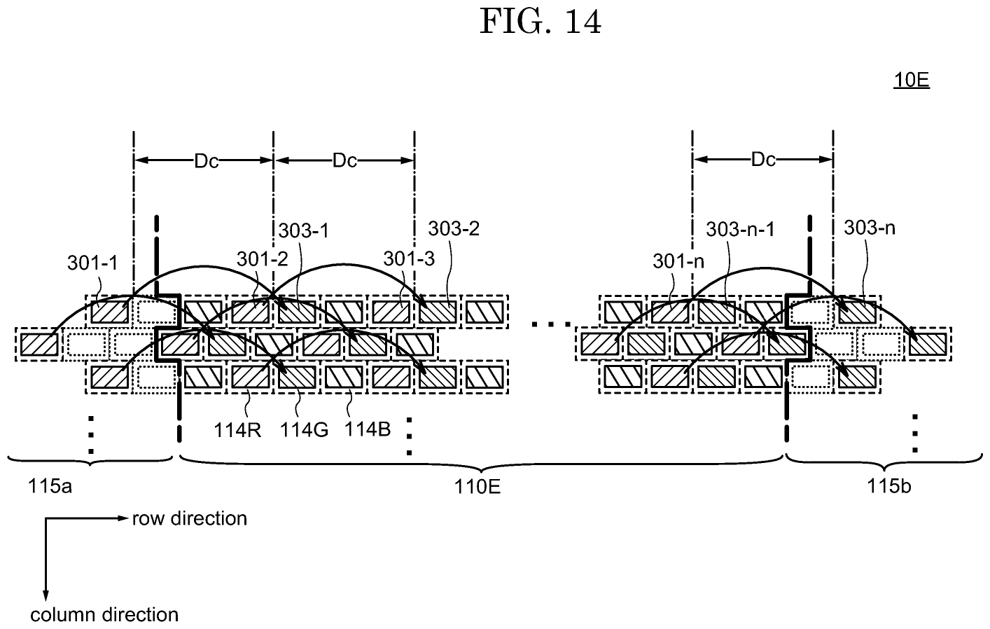

A display device 10E according to a sixth embodiment will be described with reference to FIG. 14.

Since a configuration of the display device 10E is substantially the same as that of the display device 10D according to the fifth embodiment except that no dummy area is arranged, a detailed explanation will be omitted. Hereinafter, the configuration of the display device 10E that is different from the display device 10D according to the fifth embodiment will be mainly described.

In the display device 10D according to the fifth embodiment, the non-display area 115 includes the dummy area 140 where the pseudo pixel is arranged. On the other hand, the display device 10E according to the present embodiment does not include the dummy area 140 in the non-display area 115.

FIG. 14 is a diagram showing the first deposition pattern 301, the second deposition pattern 303, and the deposition pattern of the third pixel 114B formed in the manufacturing process of the display device 10E according to the present embodiment. In FIG. 14, part of a display area 110E of the display device 10E, part of the non-display area 115 (a first area 115a) adjacent to one side of the display area 110E, and part of the non-display area 115 (second area 115b) adjacent to the other side opposite the one side of the display area 110E are shown.

Although not shown, similar to the fifth embodiment described above, also in the present embodiment, after the first deposition pattern 301 is formed on the mother substrate by using the deposition mask, the same deposition mask is moved by the distance of three pixels from the position where the deposition mask is arranged to form the first deposition pattern 301 toward the row direction of the pixel 114 to form the second deposition pattern 303. In other words, the first deposition pattern 301 and the second deposition pattern 303 formed using the same opening of the deposition mask are separated by three pixels in the row direction.

The first deposition pattern 301 may be formed not only in an area corresponding to the display area 110E of the display device 10E but also in at least part of the first area 115a adjacent to one side of the display area 110E. In the present embodiment, the dummy area where the pseudo pixel is arranged in the non-display area 115 is not included. Therefore, the deposition pattern 301 formed in the first area 115a is the dummy deposition pattern that does not contribute to the configuration of the pixel.

In FIG. 14, the same number (1, 2, 3 . . . n, n is a natural number) is added after the symbols of the first deposition pattern 301 and the second deposition pattern 303 present in the same pixel row and are formed using the same opening 203 of the deposition mask. The first deposition pattern 301-1 in the first area 115a and the second deposition pattern 303-1 in the display area 110E, which is closest to one side of the display area 110E, are formed using the same opening 203 of the deposition mask. Similarly, the first deposition pattern 301-2 in the display area 110 E, which is closest to the one side of the display area 110E, and the second deposition pattern 303-2 are formed using the same opening 203 of the deposition mask 202.

Similarly, the first deposition pattern 301-n closest to the other side of the display area 110E and the second deposition pattern 303-n closest to the other side of the display area 110E in the second area 115b are formed using the same opening 203 of the deposition mask.

As shown in FIG. 14, although the first deposition pattern 301-1 is arranged in the first area 115a, the second deposition pattern 303 is not arranged in the first area 115a. In addition, unlike the fifth embodiment, in the present embodiment, although the second deposition pattern 303-n is arranged in the second area 115b, the first deposition pattern 301 is not arranged in the second area 115b.

Although not shown, when the first deposition pattern 301 and the second deposition pattern 303 are formed in the display area 110E and in at least part of the non-display area 115, the first deposition pattern 301 and the second deposition pattern 303 are formed in the TEG area in the mother substrate in alignment with the opening of the TEG pattern. The first deposition pattern 301 and the second deposition pattern 303 formed in the TEG area are separated by three pixels in the row direction.

As described above, even when there is no dummy area 140 in the non-display area 115, the first deposition pattern 301 is formed in the non-display area 115 in addition to the display area 110E, and thereafter, the second deposition pattern 303 is formed by shifting the deposition mask by the predetermined distance Dc, in the present embodiment, by the distance of three pixels in the row direction, whereby the light-emitting layers of the first pixel 114R and the second pixel 114G can be formed using the same deposition mask. In addition, since the deposition mask is shifted by the distance of three pixels, two or more inspection TEGs are not formed in an area (an inspection area) where one inspection TEG is located in the TEG area. Therefore, it is possible to inspect the pattern deviation of the deposition pattern. Therefore, similar to the fifth embodiment, in the present embodiment as well, it is possible to improve the reliability of the display device 10E while reducing the manufacturing cost of the display device 10E by using the same deposition mask for the first pixel 114R and the second pixel 114G.

### [Modifications]

The present disclosure is not limited to the above-described embodiments, and includes various other modifications. For example, the above-described embodiments have been described in detail for the purpose of illustrating the present disclosure in an easy-to-understand manner, and are not necessarily limited to those having all the described configurations. That is, part of the configuration of each embodiment may be replaced with another configuration or may be deleted. Some modification examples will be described below.

### [First Modification]

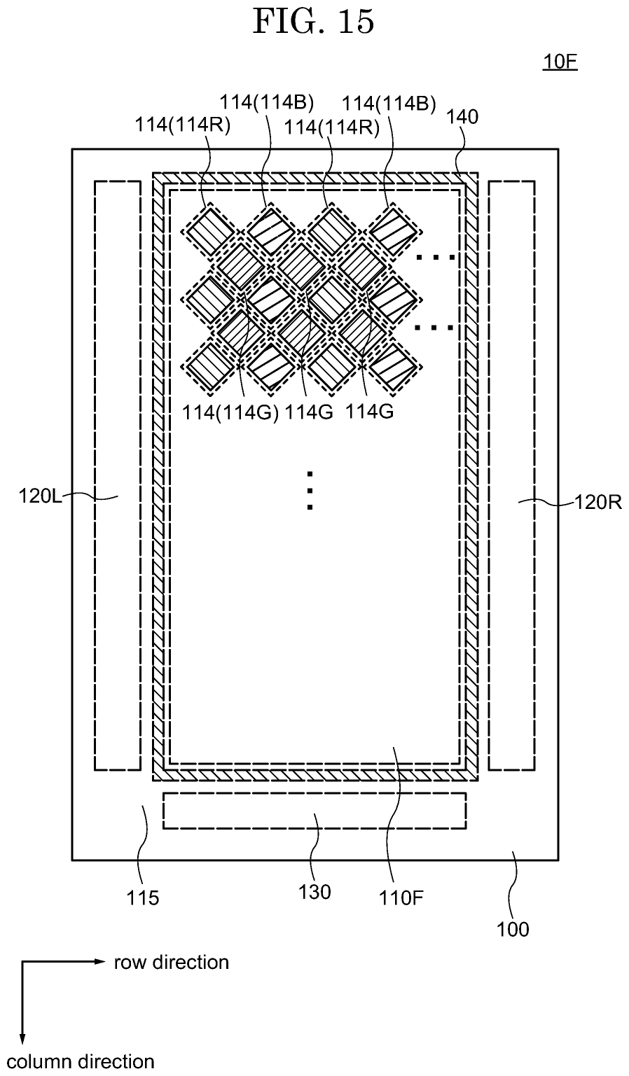

A display device 10F according to a first modification will be described below with reference to FIG. 15 to FIG. 19.

FIG. 15 is a schematic plan view of the display device 10F according to the first modification of the present disclosure. As shown in FIG. 15, since a configuration of the display device 10F is substantially the same as that of the display device 10 according to the first embodiment except for the arrangement of the pixels 114, a detailed explanation will be omitted. Hereinafter, the configuration of the display device 10F, which is different from the display device 10 according to the first embodiment, will be mainly described.

A display area 110F of the display device 10F may include the plurality of pixels 114. The plurality of pixels includes the first pixel 114R that emits red light, the second pixel 114G that emits green light, and the third pixel 114B that emits blue light. Hereinafter, when the first pixel 114R, the second pixel 114G, and the third pixel 114B are not particularly distinguished from each other, they will be referred to as the pixel 114.

As shown in FIG. 15, the arrangement of the first pixel 114R, the second pixel 114G, and the third pixel 114B is a pentile array. The size and shape of the pixels 114 are not particularly limited as long as the first pixel 114R and the second pixel 114G are the same size. In the present modification, the first pixel 114R and the third pixel 114B are alternately arranged in a predetermined pixel row, and the second pixel 114G is arranged in an adjacent pixel row.

In the display area 110F of the display device 10F, the first pixel 114R and the second pixel 114G can be formed using the same deposition mask as in the first to fourth embodiments described above.

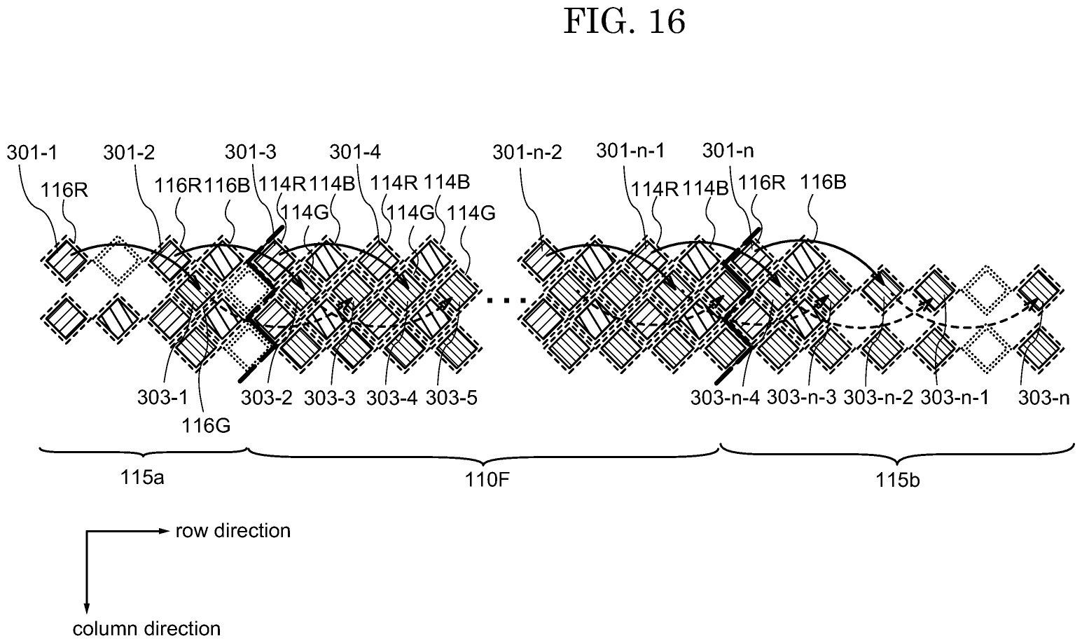

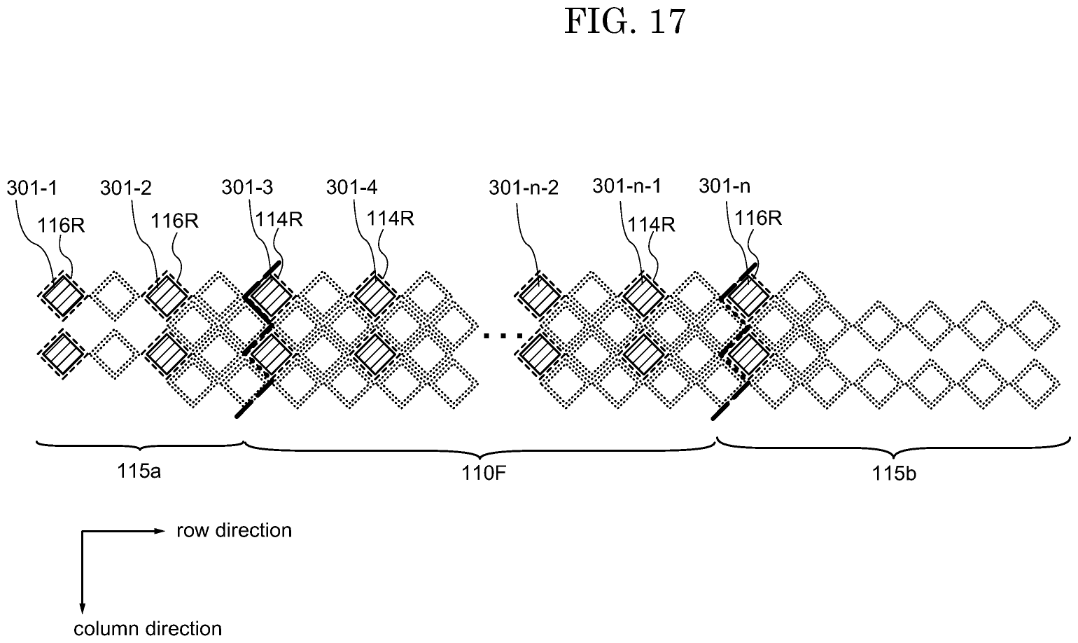

FIG. 16 is a diagram showing the first deposition pattern 301, the second deposition pattern 303, and the deposition pattern of the third pixel 114B formed in the manufacturing process of the display device 10F according to the present modification. FIG. 17 to FIG. 19 are diagrams for explaining the step of forming the first deposition pattern 301 and the second deposition pattern 303 in the manufacturing process of the display device 10F. In FIG. 16 to FIG. 19, part of the display area 110F of the display device 10F, part of the non-display area 115 (first area 115a) adjacent to one side of the display area 110F, and part of the non-display area 115 (second area 115b) adjacent to the other side opposite the one side of the display area 110F are shown.

In the present modification, the second deposition pattern 303 formed in the display area 110F is formed in two stages. After the first deposition pattern 301 is formed on the mother substrate using the deposition mask, part of the second deposition pattern 303 is formed by shifting the deposition mask used to form the first deposition pattern 301 by a predetermined first distance (a first step of forming the second deposition pattern 303). Further, after that, the deposition mask is shifted by a predetermined second distance to form the rest of the second deposition pattern 303 (a second step of forming the second deposition pattern 303). In FIG. 16, a movement of the opening of the deposition mask in the first step of forming the second deposition pattern 303 is indicated by a solid arrow, and a movement of the opening of the deposition mask in the second step of forming the second deposition pattern 303 is indicated by a dashed arrow.

Hereinafter, the step of forming the first deposition pattern 301 and the second deposition pattern 303 will be described with reference to FIG. 17 to FIG. 19.

As shown in FIG. 17, first, the first deposition pattern 301 (301-1 to 301-n, n is a natural number) is formed on the mother substrate. In the present modification, the display device 10F includes the dummy area 140 in the non-display area 115. Therefore, the light-emitting layer of the pseudo pixel 116R may be formed in the first area 115a and the second area 115b. In this case, the first deposition pattern 301 corresponding to the light-emitting layer of the pseudo pixel 116R is formed in the first area 115a and the second area 115b.

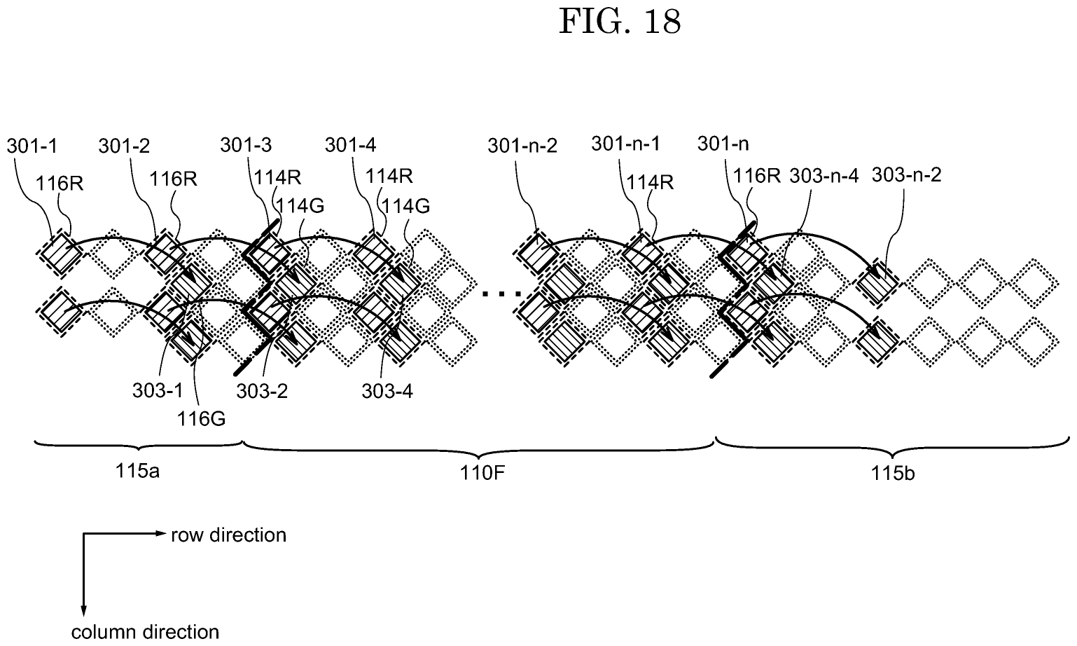

Next, part of the second deposition pattern 303 is formed by moving the deposition mask used to form the first deposition pattern 301 in a predetermined direction by a predetermined first distance. As shown in FIG. 18, in the present modification, the deposition mask is moved by 0.5 pixels in the column direction from the position arranged to form the first deposition pattern 301, and further moved by 2.5 pixels in the row direction to form part of the second deposition pattern 303 (303-1, 303-2, 303-4, . . . , 303-n−4, 303-n−2).

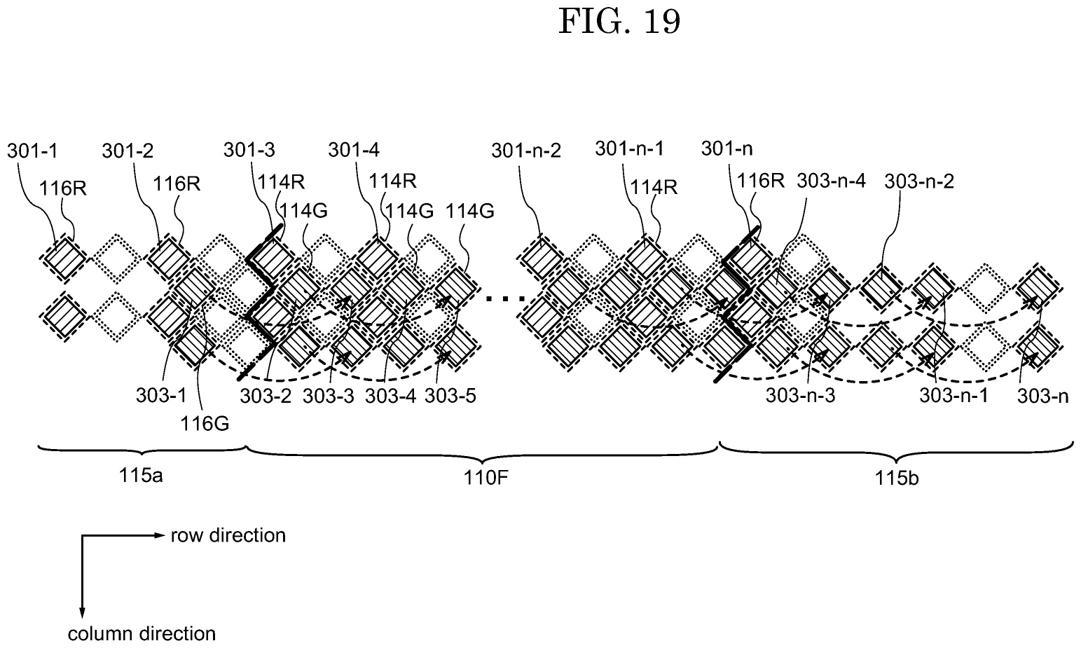

Next, the deposition mask used to form part of the second deposition pattern 303 is moved in a predetermined direction by a predetermined second distance to form the rest of the second deposition pattern 303. As shown in FIG. 19, in the present modification, the deposition mask is moved by three pixels in the row direction from the position arranged to form part of the second deposition pattern 303 to form the rest of the second deposition pattern 303 (303-3, 303-5, . . . , 303-n−3, 303-n−1, 303n).

As shown in FIG. 16 and FIG. 19, in the present modification, the first deposition pattern 301 and the second deposition pattern 303 are arranged in the first area 115a and the second area 115b, and the number of second deposition patterns 303 is larger than the number of first deposition patterns 301 in the second area 115b.

Although not shown, when the first deposition pattern 301 and the second deposition pattern 303 are formed in the display area 110F and in at least part of the non-display area 115, the first deposition pattern 301 and the second deposition pattern 303 are formed in the TEG area in the mother substrate in alignment with the opening of the TEG pattern.

As described above, in the manufacturing process of the display device 10F having the pixels 114 of the pentile array, after the first deposition pattern 301 is formed, the second deposition pattern 303 is formed by shifting the deposition mask two times from the position where the first deposition pattern 301 is formed, whereby the light-emitting layers of the first pixel 114R and the second pixel 114G can be formed using the same deposition mask. In addition, in the TEG area, since two or more inspection TEGs are not formed in the area (an inspection area) where one inspection TEG is located, it is possible to inspect the pattern deviation of the deposition pattern. Therefore, in this modification, as in the above-described embodiments, it is possible to improve the reliability of the display device 10F while reducing the manufacturing cost of the display device 10F by using the same deposition mask for the first pixel 114R and the second pixel 114G.

### [Second Modification]

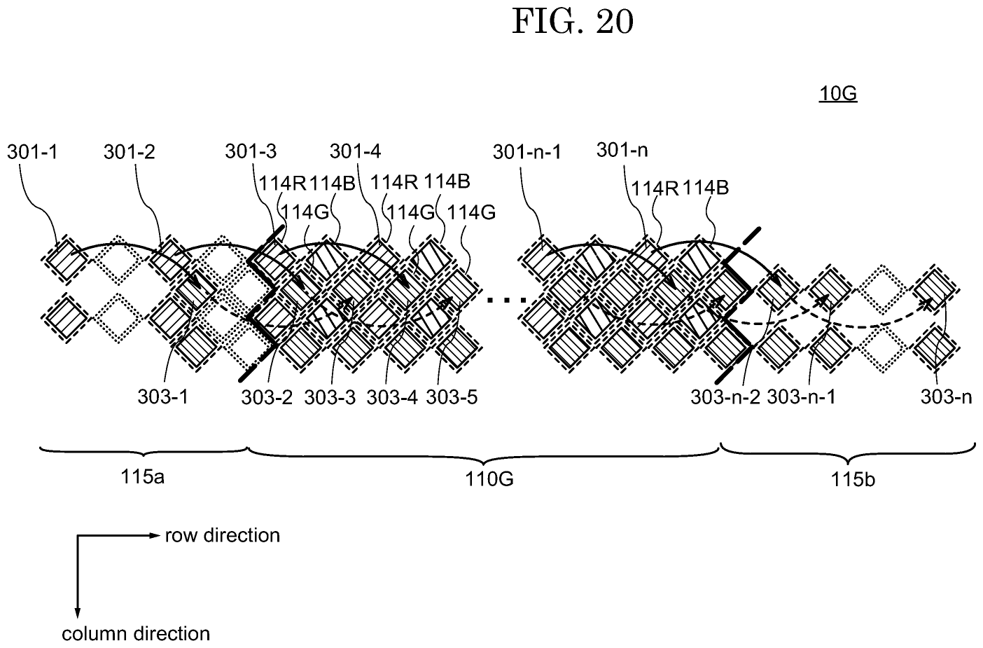

Hereinafter, a display device 10G according to a second modification will be described with reference to FIG. 20 to FIG. 23.

Since a configuration of the display device 10G is substantially the same as that of the display device 10F according to the above-described first modification except that no dummy area is arranged, a detailed explanation will be omitted. Hereinafter, the configuration of the display device 10G that is different from the display device 10F according to the first modification will be mainly described.

In the display device 10F according to the first modification, the non-display area 115 includes the dummy area 140 where the pseudo pixel is arranged. On the other hand, the display device 10G according to the present modification does not include the dummy area 140 in the non-display area 115.

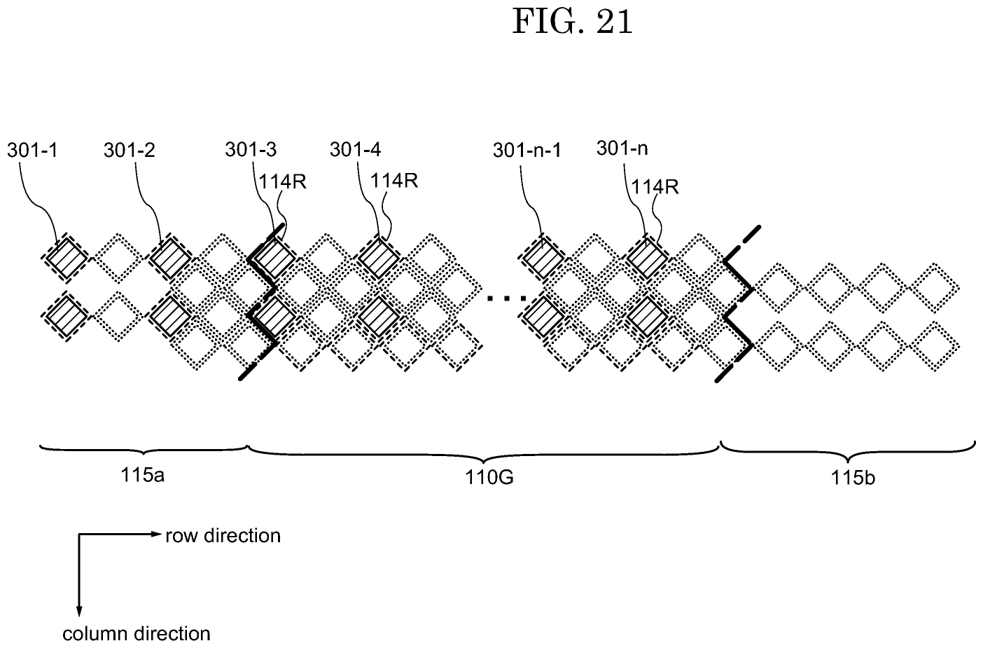

FIG. 20 is a diagram showing the first deposition pattern 301, the second deposition pattern 303, and the deposition pattern of the third pixel 114B formed in the manufacturing process of the display device 10G according to the present modification. FIG. 21 to FIG. 23 are diagrams for explaining a step of forming the first deposition pattern 301 and the second deposition pattern 303 in the manufacturing process of the display device 10G. In FIG. 20 to FIG. 23, part of the display area 110G of the display device 10G, part of the non-display area 115 (a first area 115a) adjacent to one side of the display area 110G, and part of the non-display area 115 (second area 115b) adjacent to the other side opposite the one side of the display area 110G are shown.

As in the first modification, in the present modification, the second deposition pattern 303 formed on the display area 110G is formed in two stages. In FIG. 20, the movement of the opening of the deposition mask in the first step of forming the second deposition pattern 303 is indicated by a solid arrow, and the movement of the opening of the deposition mask in the second step of forming the second deposition pattern 303 is indicated by a dashed arrow.

Hereinafter, the step of forming the first deposition pattern 301 and the second deposition pattern 303 will be described with reference to FIGS. 21 to 23.

As shown in FIG. 21, first, the first deposition pattern 301 (301-1 to 301-n, n is a natural number) is formed on the mother substrate. The first deposition pattern 301 is formed not only in the area corresponding to the display are 110G of the display device 10G but also in at least part of the first area 115a adjacent to one side of the display area 110G. In the present modification, the display device 10G does not include the dummy area 140 in the non-display area 115. Therefore, the deposition pattern 301 formed in the first area 115a is the dummy deposition pattern that does not contribute to the configuration of the pixel.

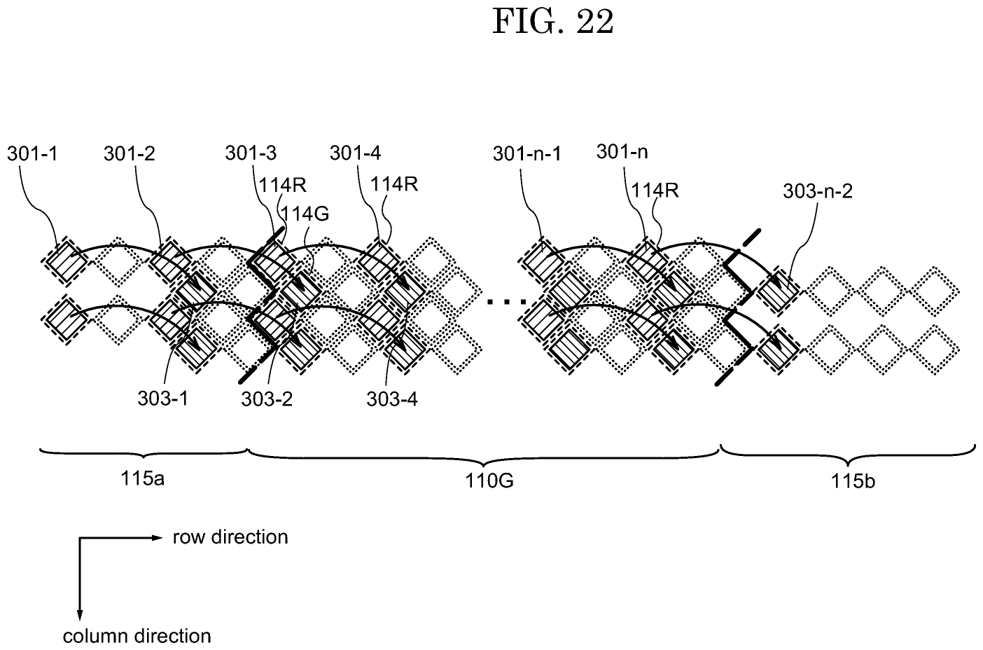

Next, part of the second deposition pattern 303 is formed by moving the deposition mask used to from the first deposition pattern 301 in a predetermined direction by a predetermined first distance. As shown in FIG. 22, in the present modification, the deposition mask is moved by 0.5 pixels in the column direction from the position arranged to form the first deposition pattern 301, and further moved by 2.5 pixels in the row direction to form part of the second deposition pattern 303 (303-1, 303-2, 303-4, . . . , 303-n−2).

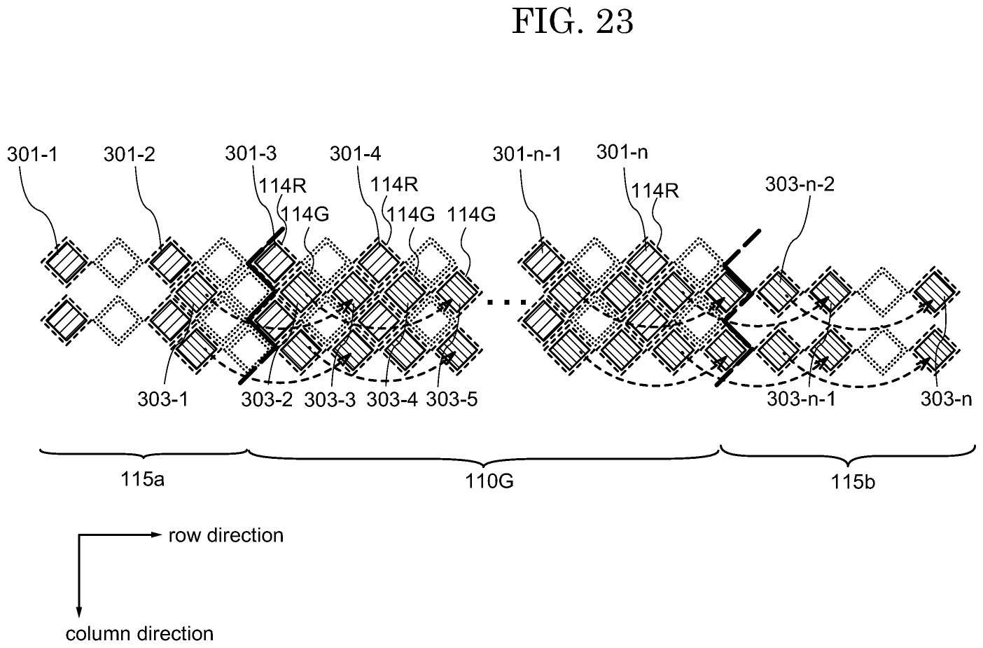

Next, the deposition mask used to form part of the second deposition pattern 303 is moved in a predetermined direction by a predetermined second distance to form the rest of the second deposition pattern 303. As shown in FIG. 23, in the present modification, the deposition mask is moved by three pixels in the row direction from the position arranged to form part of the second deposition pattern 303 to form the rest of the second deposition pattern 303 (303-3, 303-5, . . . , 303-n−1, 303n).

As shown in FIG. 20 and FIG. 23, in the present modification, although the first deposition pattern 301 and the second deposition pattern 303 are arranged in the first area 115a, the first deposition pattern 301 is not arranged in the second area 115b.

Although not shown, when the first deposition pattern 301 and the second deposition pattern 303 are formed in the display area 110G and in at least part of the non-display area 115, the first deposition pattern 301 and the second deposition pattern 303 are formed in the TEG area in the mother substrate in alignment with the opening of the TEG pattern.

As described above, even when there is no dummy area 140 in the display area 115, the first deposition pattern 301 is formed in the non-display area 115 in addition to the display area 110G, and thereafter, the second deposition pattern 303 is formed by shifting the deposition mask, whereby the light-emitting layers of the first pixel 114R and the second pixel 114G can be formed using the same deposition mask. In addition, in the TEG area, since two or more inspection TEGs are not formed in the area (an inspection area) where one inspection TEG is located, it is possible to inspect the pattern deviation of the deposition pattern. Therefore, similar to the first modification, in the present modification, it is possible to improve the reliability of the display device 10G while reducing the manufacturing cost of the display device 10G by using the same deposition mask for the first pixel 114R and the second pixel 114G.

### [Third Modification]

Although the case where the display areas 110, 1108 to 110G of the display devices 10, 10A to 10G are rectangular shapes has been described in the first to sixth embodiments, first modification and the second modification, the display area of the display device is not limited to a rectangular shape. The shape of the display area may have a circular shape, a rounded square shape, or the like.

Each of the embodiments and modifications described above as an embodiment of the present invention can be appropriately combined and implemented as long as no contradiction is caused. Further, the addition, deletion, or design change of components, or the addition, deletion, or condition change of process as appropriate by those skilled in the art based on the configurations shown in the present embodiment are also included in the scope of the present invention as long as they are provided with the gist of the present disclosure.

Further, it is understood that, even if the effect is different from those provided by each of the above-described embodiments, the effect obvious from the description in the specification or easily predicted by persons ordinarily skilled in the art is apparently derived from the present disclosure.

What is claimed is:

1. A display device comprising:
a display area arranged with a plurality of pixels, the plurality of pixels including a first pixel containing a first deposition material emitting a first color light and a second pixel containing a second deposition material emitting a second color light different from the first color light and having the same size as the first pixel; and
a non-display area located around the display area, the non-display area including a first area adjacent to one side of the display area and a second area adjacent to the other side opposite the one side of the display area,
wherein
the first area is arranged with a first deposition pattern containing the first deposition material, and the second area is arranged with a second deposition pattern containing the second deposition material and having the same size as the first deposition pattern, and
the second deposition pattern is not arranged in the first area.

2. The display device according to claim 1, wherein the first deposition pattern in the first area is separated from the second deposition pattern, which is in the same pixel row as the first deposition pattern and closest to the one side of the display area, by three pixels.

3. The display device according to claim 2, wherein the second area is arranged with the first deposition pattern in addition to the second deposition pattern.

4. The display device according to claim 3, wherein the number of the second deposition patterns is greater than the number of the first deposition patterns in the second area.

5. The display device according to claim 1, wherein the plurality of pixels is arranged in a stripe array in the display area.

6. The display device according to claim 1, wherein the plurality of pixels is arranged in a delta array in the display area.

7. The display device according to claim 1, wherein the first deposition pattern in the first area is separated from the second deposition pattern, which is in the same pixel row as the first deposition pattern and closest to the one side of the display area, by two pixels.

8. The display device according to claim 7, wherein the second area is arranged with the first deposition pattern in addition to the second deposition pattern.

9. The display device according to claim 7, wherein the plurality of pixels is arranged in an S-stripe array in the display area.

10. A display device comprising:
a display area arranged with a plurality of pixels, the plurality of pixels including a first pixel containing a first deposition material emitting a first color light and a second pixel containing a second deposition material emitting a second color light different from the first color light and having the same size as the first pixel; and
a non-display area located around the display area, the non-display area including a first area adjacent to one side of the display area and a second area adjacent to the other side opposite the one side of the display area,
wherein
the first area and the second area are arranged with a first deposition pattern containing the first deposition material and a second deposition pattern containing the second deposition material and having the same size as the first deposition pattern, and
the number of the second deposition patterns is greater than the number of the first deposition patterns in the second area.

11. A display device comprising:
a display area arranged with a plurality of pixels, the plurality of pixels including a first pixel containing a first deposition material emitting a first color light and a second pixel containing a second deposition material emitting a second color light different from the first color light and having the same size as the first pixel; and
a non-display area located around the display area, the non-display area including a first area adjacent to one side of the display area and a second area adjacent to the other side opposite the one side of the display area,
wherein
the first area is arranged with a first deposition pattern containing the first deposition material and a second deposition pattern containing the second deposition material having the same size as the first deposition pattern, the second area is arranged with the second deposition pattern, and
the first deposition pattern is not arranged in the second area.

12. The display device according to claim 10, wherein the plurality of pixels is arranged in a pentile array in the display area.

13. The display device according to claim 11, wherein the plurality of pixels is arranged in a pentile array in the display area.
